(19) United States
(12) Patent Application Publication
(10) Pub. No.: US 2026/0134891 A1
(43) Pub. Date: May 14, 2026

(54) METHOD OF MANUFACTURING VERTICALLY STACKED SEMICONDUCTOR DEVICE AND VERTICALLY STACKED SEMICONDUCTOR DEVICE

(71) Applicant: INSTITUTE OF MICROELECTRONICS, CHINESE ACADEMY OF SCIENCES, Beijing (CN)

(72) Inventors: Huaxiang YIN, Beijing (CN); Qingzhu ZHANG, Beijing (CN); Lei CAO, Beijing (CN); Qingkun LI, Beijing (CN)

(21) Appl. No.: 19/171,548

(22) Filed: Apr. 7, 2025

(30) Foreign Application Priority Data
Nov. 12, 2024 (CN) 202411612760.8

(51) Int. Cl. G11C 5/06; H10B 10/00; H10D 30/00; H10D 30/01; H10D 64/01; H10D 84/01; H10D 84/85

(52) U.S. Cl. CPC G11C 5/063; H10B 10/12; H10D 30/0191; H10D 30/502; H10D 64/017; H10D 84/017; H10D 84/0184; H10D 84/0188; H10D 84/852

(57) ABSTRACT

A vertically stacked semiconductor device and manufacturing method thereof. The method includes: sequentially providing a lower stack, an intermediate layer, and an upper stack on a substrate; patterning the lower stack, the intermediate layer, the upper stack and an upper portion of the substrate; forming a sacrificial gate on the substrate; forming a gate spacer on a sidewall of the sacrificial gate; patterning the lower stack, the intermediate layer, and the upper stack; selectively etching the sacrificial layer and the intermediate layer; filling a space released by selective etching the sacrificial layer and the intermediate layer with a dielectric material; forming a lower source/drain layer adjacent to an exposed side surface of the channel layer in the lower stack, forming an upper source/drain layer adjacent to an exposed side surface of the channel layer in the upper stack; replacing the sacrificial gate and the sacrificial layer with a gate stack.

This application claims the benefit of priority to Chinese Patent Application No. 202411612760.8, filed on Nov. 12, 2024. The entire contents of this application are hereby incorporated herein by reference.

### TECHNICAL FIELD

The present disclosure relates to a field of semiconductor technology, and in particular, to a method of manufacturing a vertically stacked semiconductor device and a vertically stacked semiconductor device.

### BACKGROUND

With the continuous development of manufacturing process nodes and key technologies of integrated circuits, NS-GAA FET (Nano-Sheet Gate-All-Around Field-Effect Transistor) will replace the existing Fin FET (Fin Field-Effect Transistor) technology at 3 nm node and below. Furthermore, three-dimensional stacked transistors will become the main technological route after the 1 nm node. The three-dimensional stacked transistors include three-dimensional stacked integrated transistors and VFETs (Vertical Field-Effect Transistors). The three-dimensional stacked integrated transistor is also known as 3DS FET or CFET (Complementary Field Effect Transistor).

The main process method for implementing 3DS FET has two types: one is sequential integration, and the other is self-aligned monolithic (or single) integration. The former process method is simple, but it is limited by performance and resources. The latter process method has high integration and superior performance, but it is complex and presents multiple process technology challenges.

### SUMMARY

The present disclosure provides a method of manufacturing a vertically stacked semiconductor device and a vertically stacked semiconductor device.

According to an aspect of the present disclosure, a method of manufacturing a vertically stacked semiconductor device is provided, including: sequentially providing a lower stack, an intermediate layer, and an upper stack on a substrate, each of the lower stack and the upper stack including channel layers and sacrificial layers provided alternately, and the sacrificial layer and the intermediate layer having etching selectivity relative to the substrate and the channel layer; patterning the lower stack, the intermediate layer, the upper stack and an upper portion of the substrate to form a fin extending in a first direction; forming a sacrificial gate extending in a second direction intersecting the first direction on the substrate to intersect with the fin; forming a gate spacer on a sidewall of the sacrificial gate; patterning the lower stack, the intermediate layer, and the upper stack using the sacrificial gate and the gate spacer as a mask, so that the patterned lower stack, the patterned intermediate layer, and the patterned upper stack include a side surface exposed in the first direction; selectively etching the sacrificial layer and the intermediate layer via the exposed side surface, where in the selective etching, an etching rate of the intermediate layer is greater than an etching rate of the sacrificial layer, so that when the selective etching is completed, the intermediate layer is removed, the sacrificial layer is retained, and an end portion of the retained sacrificial layer in the first direction is recessed relative to the channel layer; filling a space released by the selective etching of the sacrificial layer and the intermediate layer in the fin with a dielectric material, where a portion of the dielectric material filled at the end portion of the retained sacrificial layer is used as an inner spacer, and a portion of the dielectric material filled between the lower stack and the upper stack is used as an inter-device isolation layer; forming a lower source/drain layer adjacent to an exposed side surface of the channel layer in the lower stack, and forming an upper source/drain layer adjacent to an exposed side surface of the channel layer in the upper stack; and replacing the sacrificial gate and the sacrificial layer with a gate stack.

According to embodiments of the present disclosure, a material type of the intermediate layer is identical to a material type of the sacrificial layer, and an element doping ratio of the intermediate layer is different from an element doping ratio of the sacrificial layer, so that the etching rate of the intermediate layer is greater than the etching rate of the sacrificial layer.

According to embodiments of the present disclosure, the method further includes: forming an intermediate dielectric layer covering the upper stack, the upper source/drain layer, and the lower source/drain layer; etching the intermediate dielectric layer to form a dielectric layer opening exposing the upper source/drain layer and the lower source/drain layer; and providing a conductive material in the dielectric layer opening to form a contact hole, where the contact hole in the intermediate dielectric layer allows an upper drain layer and a lower drain layer to be electrically connected to a data output terminal through the contact hole, and allows: a non-powered lower source layer that is not electrically connected to a power supply to be electrically connected to a ground terminal, and an upper source layer located directly above the non-powered lower source layer to be electrically connected to the ground terminal; or an upper source layer located directly above a powered lower source layer electrically connected to the power supply to be electrically connected to a bit line terminal.

According to embodiments of the present disclosure, a shallow trench isolation component is provided next to the upper portion of the substrate; the shallow trench isolation component is pre-embedded with a power rail for electrically connecting to the power supply; and the method further includes: etching the shallow trench isolation component according to a position of the lower source layer and a position of the power rail, so as to form an isolation component opening that exposes the lower source layer and the power rail; and filling the isolation component opening with a conductive material, and sealing the isolation component opening with a dielectric material after filling the conductive material, so as to form a contact hole for electrically connecting the lower source layer to the power rail.

According to embodiments of the present disclosure, the forming a lower source/drain layer adjacent to an exposed side surface of the channel layer in the lower stack and forming an upper source/drain layer adjacent to an exposed side surface of the channel layer in the upper stack includes: forming a protective spacer on the substrate to protect the upper stack; forming a first electrode material layer adjacent to the lower stack in an unprotected region between the protective spacer and the substrate; in-situ doping the first electrode material layer to obtain the lower source/drain layer; depositing a dielectric material on the lower source/drain layer to form the inter-device isolation layer isolating the lower source/drain layer from the upper source/drain layer; removing the protective spacer exposed outside the inter-device isolation layer; forming a second electrode material layer adjacent to the upper stack on the inter-device isolation layer; in-situ doping the second electrode material layer to form the upper source/drain layer; and activating the lower source/drain layer and the upper source/drain layer.

According to another aspect of the present disclosure, a vertically stacked semiconductor device is provided, including: a first field-effect transistor and a second field-effect transistor stacked in a vertical direction on a substrate; and an inter-device isolation layer between the first field-effect transistor and the second field-effect transistor, where each of the first field-effect transistor and the second field-effect transistor includes: a plurality of channel layers stacked spaced apart from each other in the vertical direction; source/drain layers adjacent to the plurality of channel layers on both sides of the plurality of channel layers in a first direction; a gate stack extending in a second direction intersecting the first direction and surrounding the plurality of channel layers; and an inner spacer between the gate stack and the source/drain layers, where an outer surface of the inner spacer of the first field-effect transistor is substantially aligned with an outer surface of the inner spacer of the second field-effect transistor.

According to embodiments of the present disclosure, the inter-device isolation layer is integrated with the inner spacer adjacent to the inter-device isolation layer.

According to embodiments of the present disclosure, in the first field-effect transistor, the gate stack includes a portion on an upper surface of a topmost channel layer among the plurality of channel layers in the first field-effect transistor; and in the second field-effect transistor, the gate stack includes a portion on a lower surface of a bottommost channel layer among the plurality of channel layers in the second field-effect transistor.

According to embodiments of the present disclosure, a plurality of groups of vertically stacked field-effect transistors are provided, each group of vertically stacked field-effect transistors includes the first field-effect transistor and the second field-effect transistor stacked vertically, two groups of vertically stacked field-effect transistors among the plurality of groups of vertically stacked field-effect transistors form an inverter structure, and a plurality of inverter structures in the vertically stacked semiconductor device are cross coupled with each other to form an SRAM structure.

According to embodiments of the present disclosure, for the two groups of vertically stacked field-effect transistors used to form the inverter structure, drain layers of the two groups of vertically stacked field-effect transistors are shared, and the shared drain layers are electrically connected to a signal output terminal; and among the two groups of vertically stacked field-effect transistors, two source layers of one group of vertically stacked field-effect transistors are electrically connected to a ground terminal, and two source layers of the other group of vertically stacked field-effect transistors are electrically connected to a bit line terminal and a power rail, respectively.

### BRIEF DESCRIPTION OF THE DRAWINGS

The above and other objectives, features, and advantages of the present disclosure will become clearer through the following description of embodiments of the present disclosure with reference to the accompanying drawings. This application contains at least one drawing executed in color. Copies of this patent application with color drawings will be provided by the Office upon request and payment of the necessary fee. In the drawings:

FIG. 1 shows a schematic diagram of a development process of an integrated circuit according to an embodiment of the present disclosure.

FIG. 2 shows a schematic diagram of an evolution path of a core transistor structure of an integrated circuit according to an embodiment of the present disclosure.

FIG. 3 shows a schematic diagram of a sequential integration process according to an embodiment of the present disclosure.

FIG. 4 shows a schematic diagram of a self-aligned monolithic integration process according to an embodiment of the present disclosure.

FIG. 5 shows a schematic flowchart of a method of manufacturing a vertically stacked semiconductor device according to an embodiment of the present disclosure.

FIG. 6 shows a schematic diagram of an SRAM integrated circuit according to an embodiment of the present disclosure.

FIG. 7 shows a schematic diagram of a single-layer SRAM structure according to an embodiment of the present disclosure.

FIG. 8A shows a schematic diagram of a layer structure of a vertically stacked semiconductor device according to an embodiment of the present disclosure.

FIG. 8B shows a schematic diagram of a top layer structure of a vertically stacked semiconductor device according to an embodiment of the present disclosure.

FIG. 8C shows a schematic diagram of a bottom layer structure of a vertically stacked semiconductor device according to an embodiment of the present disclosure.

FIG. 9A shows a schematic diagram of an axial direction of a vertically stacked semiconductor device extending in a first direction according to an embodiment of the present disclosure.

FIG. 9B shows a schematic diagram of an axial direction of a vertically stacked semiconductor device extending in a second direction according to an embodiment of the present disclosure.

FIGS. 10A to 10E show schematic diagrams of various axial directions of a layer structure of a vertically stacked semiconductor device according to an embodiment of the present disclosure.

FIGS. 11A to 48A, 11B to 48B, 32C, 32D, 48C, and 48D show schematic cross-sectional views of a vertically stacked semiconductor device in an axial direction according to an embodiment of the present disclosure.

FIG. 18B′, 22A′ to 24A′, 22B′ to 24B′, 26A′, 32A′, 32B′, 32C′, 32D′, 34A′, 35A′, 45A′, 48A′, 48B′, 48C′ and 48D′ show schematic cross-sectional views of a semiconductor device in an axial direction in the related art.

FIG. 49 shows a schematic structural diagram of a vertically stacked semiconductor device according to an embodiment of the present disclosure.

FIG. 50 shows a schematic diagram of an SRAM structure implemented based on a vertically stacked semiconductor device according to an embodiment of the present disclosure.

### DETAILED DESCRIPTION OF EMBODIMENTS

In order to make the purpose, technical solution, and advantages of the present disclosure clearer and more understandable, the following will provide further detailed descriptions of the present disclosure in conjunction with specific embodiments and with reference to the accompanying drawings.

The terms used here are only for describing specific embodiments and are not intended to limit the present disclosure. The terms “include”, “contain”, “comprise”, etc. used herein indicate the presence of the described features, steps, operations, and/or components, but do not exclude the presence or addition of one or more other features, steps, operations, or components.

All terms used herein, including technical and scientific terms, have meanings commonly understood by those skilled in the art, unless otherwise defined. It should be noted that the terms used here should be interpreted as having meanings consistent with the context of the present disclosure, and should not be interpreted in an idealized or overly rigid manner.

When using an expression, for example “at least one of A, B, and C”, the expression may generally be interpreted according to the meaning commonly understood by those skilled in the art. For example, “a system with at least one of A, B, and C” may refer to, but is not limited to, a system with A alone, a system with B alone, a system with C alone, a system with A and B, a system with A and C, a system with B and C, or a system with A, B, and C. When using the expression, for example “at least one of A, B, or C”, the expression may generally be interpreted according to the meaning commonly understood by those skilled in the art. For example, “a system with at least one of A, B, or C” may refer to, but is not limited to, a system with A alone, a system with B alone, a system with C alone, a system with A and B, a system with A and C, a system with B and C, or a system with A, B, and C.

It should also be noted that the directional terms described in embodiments, such as “up”, “down”, “front”, “back”, “left”, “right”, etc., are only for reference to the directions in the accompanying drawings and are not intended to limit the scope of protection of the present disclosure. Throughout the accompanying drawings, the same elements are represented by the same or similar reference numerals. Conventional structures or constructions will be omitted when they may cause confusion in the understanding of the present disclosure.

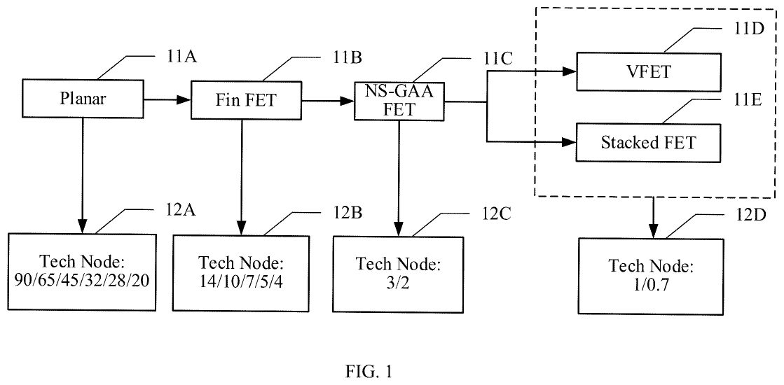

In embodiments of the present disclosure, the development process of integrated circuits is demonstrated using the technology development route shown in FIG. 1 as an example. It should be noted that in FIG. 1, Tech Node refers to the semiconductor process node, which may be used to represent the critical dimensions that may be achieved in the manufacturing processes of integrated circuits. On this basis, referring to the technological development route shown in FIG. 1, it may be seen that the manufacturing processes of integrated circuits are ranked in descending order of the dimensions represented by the semiconductor process nodes, namely Planar 11A (i.e., planar transistor structure), Fin FET 11B, NS-GAA FET 11C, VFET 11D, and Stacked FET 11E. The dimensions represented by Tech Node 12A of Planar 11A are 90, 65, 45, 32, 28, and 20 in descending order, with units in nm. The dimensions represented by Tech Node 12B of Fin FET 11B are 14, 10, 7, 5, and 4 in descending order, with units in nm. The dimensions represented by Tech Node 12C of NS-GAA FET 11C are 3 and 2 in descending order, with units in nm. The dimensions represented by Tech Node 12D of VFET 11D and Stacked FET 11E are 1 and 0.7 in descending order, with units in nm.

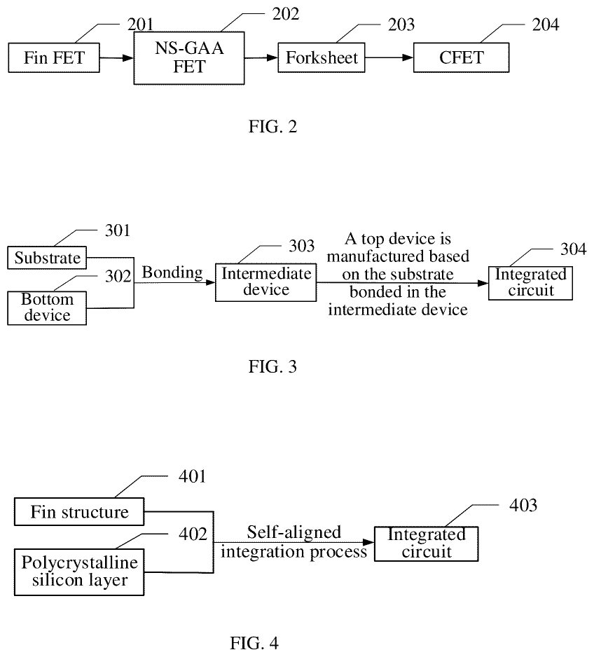

Furthermore, as shown in FIG. 2, in the evolution path of the core transistor structure of integrated circuits, it will go from Fin FET 201 to NS-GAA FET 202, Forksheet 203, and further develop to three-dimensional stacked integrated transistors within a single chip, namely 3DS FET or CFET (Complementary Field Effect Transistor) 204, so as to achieve higher integration density and higher overall performance.

As shown in FIG. 3 and FIG. 4, the main process method for implementing 3DS FET has two types: one is sequential integration process (Sequential 3D), and the other is self-aligned monolithic integration process (Monolithic 3D). Taking the stacked two transistors as an example, if the two transistors are fabricated using the sequential integration process, the channel materials of the two transistors may be different from each other; if the two transistors are fabricated using the self-aligned monolithic integration process, the channel materials of the two transistors may be the same. For example, the operation of the sequential integration process may include: bonding a substrate 301 to an upper portion of a bottom device 302 to obtain an intermediate device 303; and manufacturing a top device based on the substrate bonded in the intermediate device to obtain an integrated circuit 304. The self-aligned monolithic integration process may include: directly growing a polycrystalline silicon layer 402 surrounding a plurality of channel layers on a fin structure 401, and then processing the obtained structure to obtain an integrated circuit 403.

On this basis, the sequential integration process method is simple, but it is limited by performance and resources. The latter self-aligned monolithic integration process method has high integration and superior performance, but it is complex and presents multiple process technology challenges.

For example, the advantages of sequential integration process include flexible architecture design, adjustable channel materials as needed, flexible connection methods between transistors, etc. The disadvantages of sequential integration process mainly include high resource consumption, limitations in the manufacturing process, adhesion, isolation space between N-P, heat budget, and photolithography alignment.

The advantages of self-aligned monolithic integration process include low resource consumption, precise process control, such as self-aligned top and bottom devices, and narrow isolation space between N-P, etc. The main disadvantage of self-aligned monolithic integration process is high process difficulty, such as processes with high aspect ratios, and inter-device interconnections, etc.

In view of this, the present disclosure provides a method of manufacturing a vertically stacked semiconductor device, including: sequentially providing a lower stack, an intermediate layer, and an upper stack on a substrate, where each of the lower stack and the upper stack includes alternately provided channel layers and sacrificial layers, and the sacrificial layer and the intermediate layer have etching selectivity relative to the substrate and the channel layer; patterning the lower stack, the intermediate layer, the upper stack and an upper portion of the substrate to form a fin extending in a first direction; forming a sacrificial gate extending in a second direction intersecting the first direction on the substrate to intersect with the fin; forming a gate spacer on a sidewall of the sacrificial gate; patterning the lower stack, the intermediate layer, and the upper stack using the sacrificial gate and the gate spacer as a mask, so that the patterned lower stack, the patterned intermediate layer, and the patterned upper stack include a side surface exposed in the first direction; selectively etching the sacrificial layer and the intermediate layer via the exposed side surface, where in the selective etching, an etching rate of the intermediate layer is greater than an etching rate of the sacrificial layer, so that when the selective etching is completed, the intermediate layer is removed, the sacrificial layer is retained, and an end portion of the retained sacrificial layer in the first direction is recessed relative to the channel layer; filling a space released by the selective etching of the sacrificial layer and the intermediate layer in the fin with a dielectric material, where a portion of the dielectric material filled at the end portion of the retained sacrificial layer is used as an inner spacer, and a portion of the dielectric material filled between the lower stack and the upper stack is used as an inter-device isolation layer; forming a lower source/drain layer adjacent to an exposed side surface of the channel layer in the lower stack, and forming an upper source/drain layer adjacent to an exposed side surface of the channel layer in the upper stack; and replacing the sacrificial gate and the sacrificial layer with a gate stack. According to embodiments of the present disclosure, the intermediate layer and the sacrificial layer with etching selectivity relative to the substrate and the channel layer are provided in the fin, and the etching rate of the intermediate layer is set to be greater than that of the sacrificial layer. Based on this, selective etching is performed on the intermediate layer and the sacrificial layer. When the selective etching is completed, the intermediate layer is removed while the sacrificial layer is retained, and the end portion of the retained sacrificial layer in the first direction is recessed relative to the channel layer. The space released by selective etching of the sacrificial layer and the intermediate layer in the fin is filled with a dielectric material, so as to form the inter-device isolation layer and the inner spacer, achieving the monolithic manufacturing of the inter-device isolation layer and the inner spacer, reducing process steps, and avoiding the formation of the inter-device isolation layer and the inner spacer in multiple sequential steps. On this basis, in the vertically stacked semiconductor device manufactured by the monolithic manufacturing method of the inter-device isolation layer and the inner spacer, the upper source/drain layer of the field-effect transistor located above and the lower source/drain layer of the field-effect transistor located below are symmetrical, avoiding the adverse result of the volume of the field-effect transistor structure located above being greater than that of the field-effect transistor structure located below in sequential manufacturing.

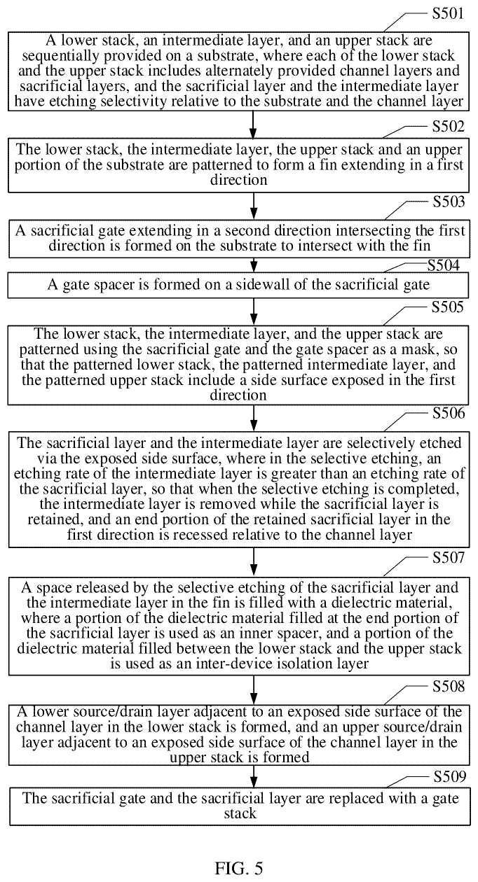

FIG. 5 shows a schematic flowchart of a method of manufacturing a vertically stacked semiconductor device according to an embodiment of the present disclosure.

As shown in FIG. 5, the method of manufacturing the vertically stacked semiconductor device in this embodiment includes operations S501 to S509.

In operation S501, a lower stack, an intermediate layer, and an upper stack are sequentially provided on a substrate. Each of the lower stack and the upper stack includes alternately provided channel layers and sacrificial layers, and the sacrificial layer and the intermediate layer have etching selectivity relative to the substrate and the channel layer.

In operation S502, the lower stack, the intermediate layer, the upper stack and an upper portion of the substrate are patterned to form a fin extending in a first direction.

In operation S503, a sacrificial gate extending in a second direction intersecting the first direction is formed on the substrate to intersect with the fin.

In operation S504, a gate spacer is formed on a sidewall of the sacrificial gate.

In operation S505, the lower stack, the intermediate layer, and the upper stack are patterned using the sacrificial gate and the gate spacer as a mask, so that the patterned lower stack, the patterned intermediate layer, and the patterned upper stack include a side surface exposed in the first direction.

In operation S506, the sacrificial layer and the intermediate layer are selectively etched via the exposed side surface, where in the selective etching, an etching rate of the intermediate layer is greater than an etching rate of the sacrificial layer, so that when the selective etching is completed, the intermediate layer is removed while the sacrificial layer is retained, and an end portion of the retained sacrificial layer in the first direction is recessed relative to the channel layer.

In operation S507, a space released by the selective etching of the sacrificial layer and the intermediate layer in the fin is filled with a dielectric material, where a portion of the dielectric material filled at the end portion of the sacrificial layer is used as an inner spacer, and a portion of the dielectric material filled between the lower stack and the upper stack is used as an inter-device isolation layer.

In operation S508, a lower source/drain layer adjacent to an exposed side surface of the channel layer in the lower stack is formed, and an upper source/drain layer adjacent to an exposed side surface of the channel layer in the upper stack is formed.

In operation S509, the sacrificial gate and the sacrificial layer are replaced with a gate stack.

According to embodiments of the present disclosure, the vertical semiconductor device obtained by the manufacturing method of the present disclosure may be used to implement the SRAM (Static Random Access Memory) structure. For example, a first group of field-effect transistors and a second group of field-effect transistors may be arranged in the second direction and spaced apart from each other. Each group among the first group of field-effect transistors and the second group of field-effect transistors includes two vertically stacked semiconductor devices. Each vertically stacked semiconductor device may include vertically stacked field-effect transistors. On this basis, the above-described SRAM structure may be implemented based on the two groups of stacked field-effect transistors in the first group of field-effect transistors and the two groups of stacked field-effect transistors in the second group of field-effect transistors.

Taking the implementation of SRAM structure as an example, the method of manufacturing the vertical semiconductor device in embodiments of the present disclosure will be described below. It should be understood that the SRAM used here is only an example, and those skilled in the art may implement other integrated circuit structures based on the vertical semiconductor device in embodiments of the present disclosure according to their needs.

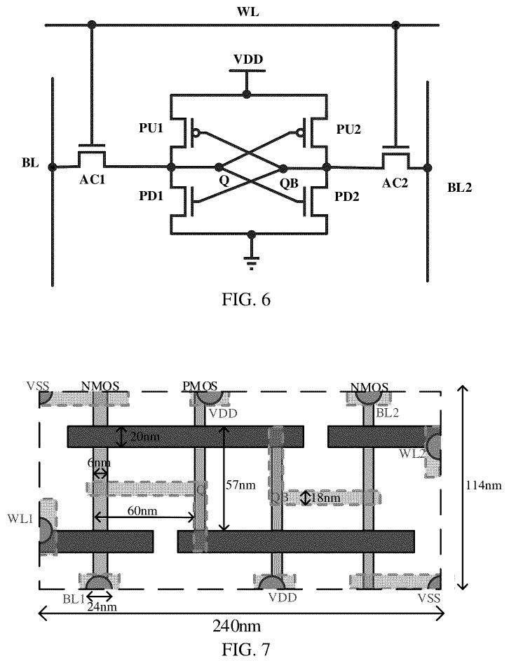

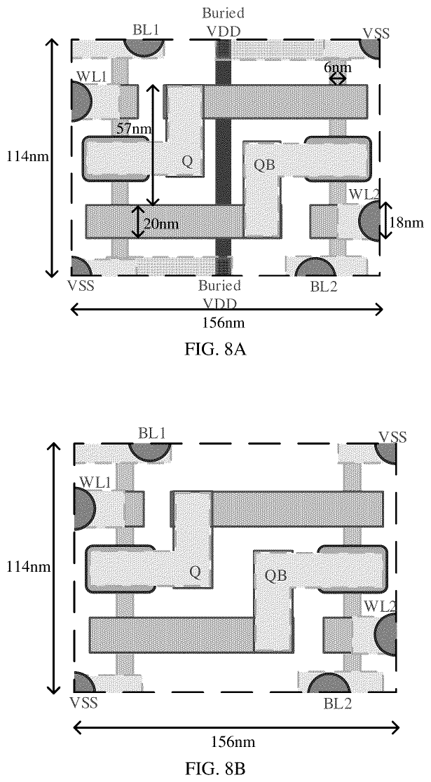

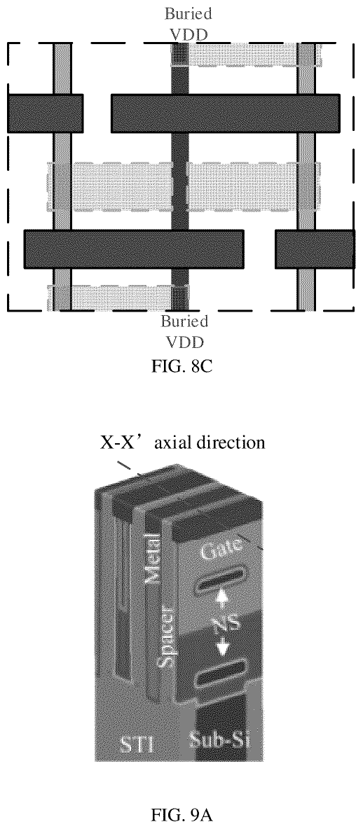

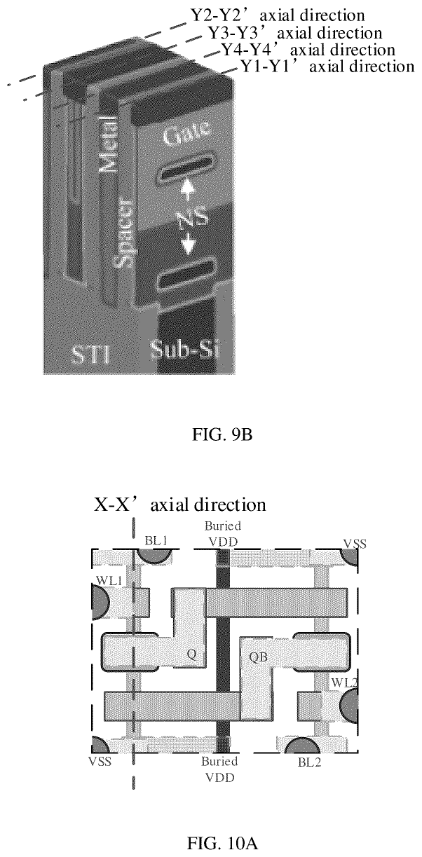

As shown in FIG. 6, SRAM is the core cell circuit of integrated circuits, and the continuous reduction of SRAM cell area is the main line of integrated circuit development. The use of three-dimensional stacked transistor structures (3DS-FET or CFET) may significantly reduce the SRAM cell area, with a reduction of over 30% in SRAM cell area. Referring to FIG. 7 and FIG. 8A, comparing the single-layer SRAM structure in FIG. 7 with the double-layer SRAM structure in FIG. 8A, it may be seen that the area of the three-dimensional stacked structure implemented in FIG. 8A is smaller than that of the two-dimensional structure in FIG. 7. Furthermore, the three-dimensional stacked structure in FIG. 8A may be divided into a top layer structure and a bottom layer structure, where the top layer structure may be implemented based on NMOS and the bottom layer structure may be implemented based on PMOS. On this basis, FIGS. 8B and 8C respectively show the top and bottom layer structures of the three-dimensional stacked structure in FIG. 8A. It should be noted that the dimensions indicated in the accompanying drawings of the present disclosure are examples and are not intended to limit the actual dimensions of the staggered cells in the present disclosure.

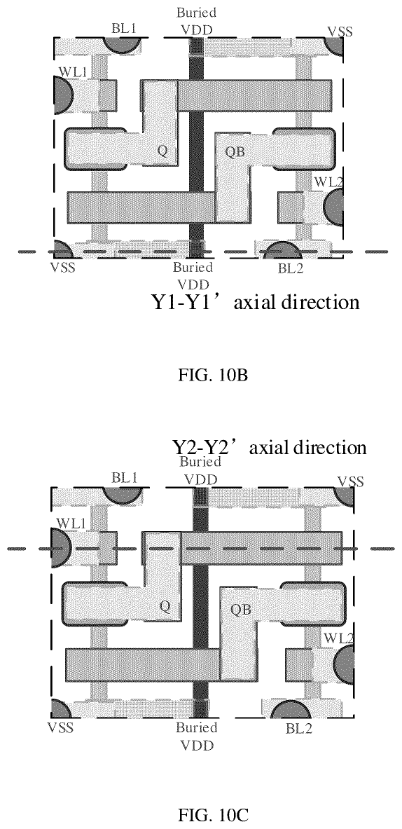

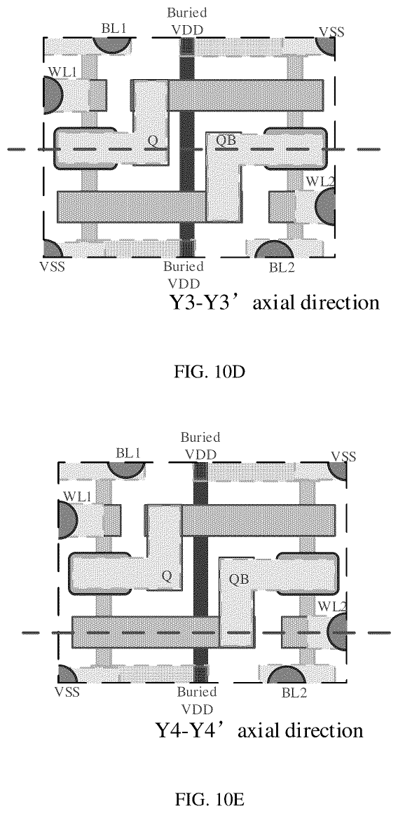

Taking SRAM as an example, various axial directions of the vertically stacked semiconductor device defined in embodiments of the present disclosure are shown in FIGS. 10A and 10B. FIGS. 10A to 10E show the various axial directions of the layer structure of the vertically stacked semiconductor device used to implement SRAM in FIG. 8A. The X-X′ axial direction extends in the first direction. The Y1-Y1′ axial direction, the Y2-Y2′ axial direction, the Y3-Y3′ axial direction, and the Y4-Y4′ axial direction extend in the second direction.

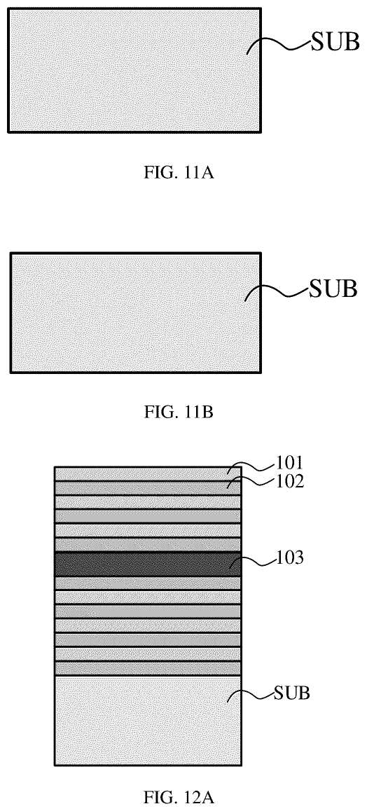

With reference to the cross-sectional views in various axial directions in the process of manufacturing the vertical semiconductor device, namely FIGS. 11A to 48A, FIGS. 11B to 48B, FIG. 32C, FIG. 32D, FIG. 48C, and FIG. 48D, the content of embodiments of the present disclosure will be described. It should be noted that in the various figures shown in the present disclosure, if the numbers in the FIG. labels of multiple figures are the same, the manufacturing processes corresponding to the multiple figures are the same. If the numbers in the FIG. labels of multiple figures are the same and the letters in the FIG. labels are different, the manufacturing processes corresponding to the multiple figures are the same, and the axial directions corresponding to the multiple figures are different. For example, FIGS. 11A and 11B are cross-sectional views in two axial directions in the same manufacturing process.

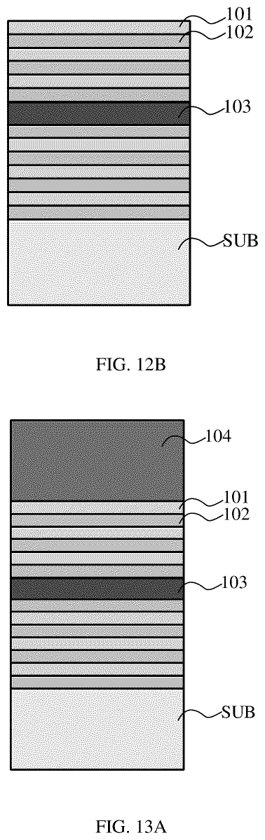

Taking a group of stacked field-effect transistors as an example, FIG. 11A and FIG. 12A are cross-sectional views in the X-X′ axial direction in the process of manufacturing the vertical semiconductor device. FIG. 11B and FIG. 12B are cross-sectional views in the Y4-Y4′ axial direction in the process of manufacturing the vertical semiconductor device. Referring to FIG. 11A and FIG. 12A and FIG. 11B and FIG. 12B, a material of the substrate SUB may include silicon, etc. Pre-treatment operations such as well photolithography, ion implantation, annealing, and cleaning may be sequentially performed on the substrate SUB. Then, the lower stack, the intermediate layer 103, and the upper stack are sequentially provided on the pretreated substrate SUB using the epitaxial growth process. Each of the lower stack and the upper stack includes alternately provided channel layers 101 and sacrificial layers 102. A material of the sacrificial layer 102 may be identical to a material of the intermediate layer 103, such as SiGe or Si. A material of the channel layer 101 may be doped silicon or the like. The doping element of the channel layer 101 located above the intermediate layer 103 and the doping element of the channel layer 101 located below the intermediate layer 103 may be the same or different.

In an embodiment of the present disclosure, the material of the channel layer 101 located above the intermediate layer 103 may include p-type doped silicon; and the material of the channel layer 101 located below the intermediate layer 103 may include n-type doped silicon. In another embodiment of the present disclosure, the material of the channel layer 101 located above the intermediate layer 103 may be n-type doped silicon; and the material of the channel layer 101 located below the intermediate layer 103 may be p-type doped silicon. In yet another embodiment of the present disclosure, the material of the channel layer 101 located above the intermediate layer 103 and the material of the channel layer 101 located below the intermediate layer 103 may both be n-type doped silicon or may both be p-type doped silicon.

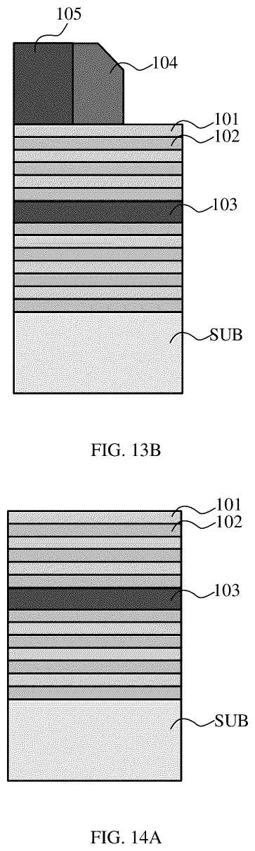

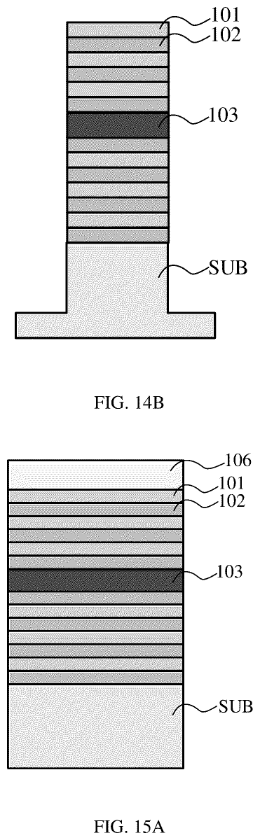

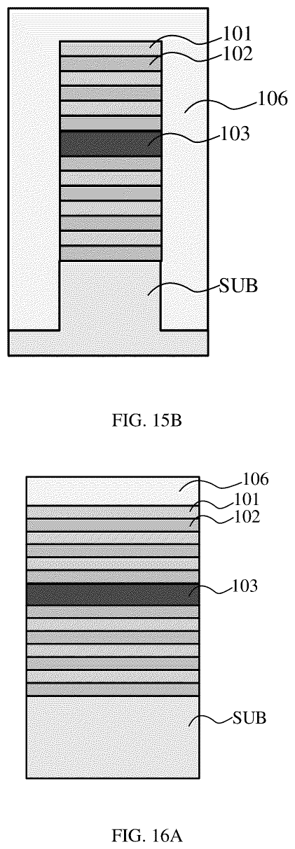

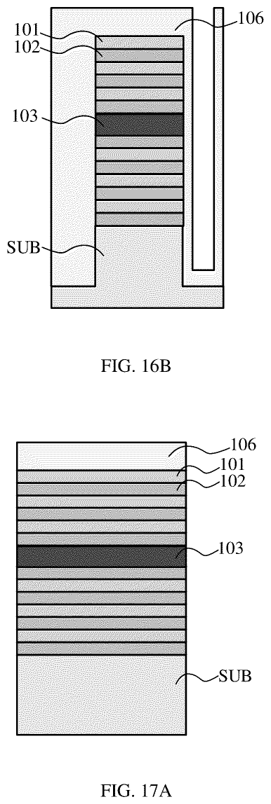

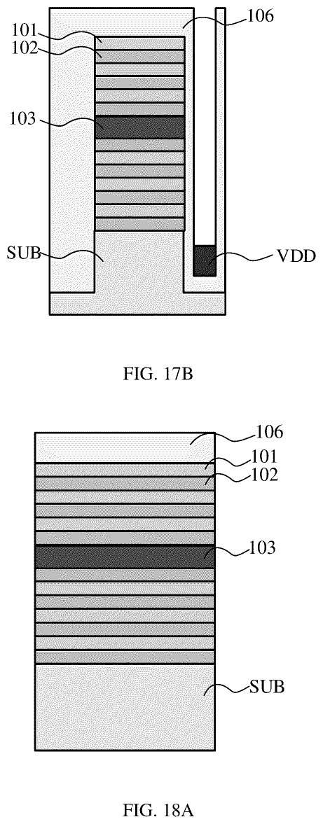

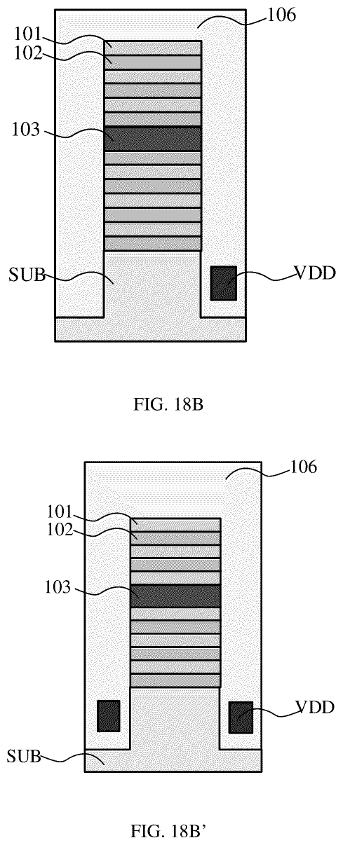

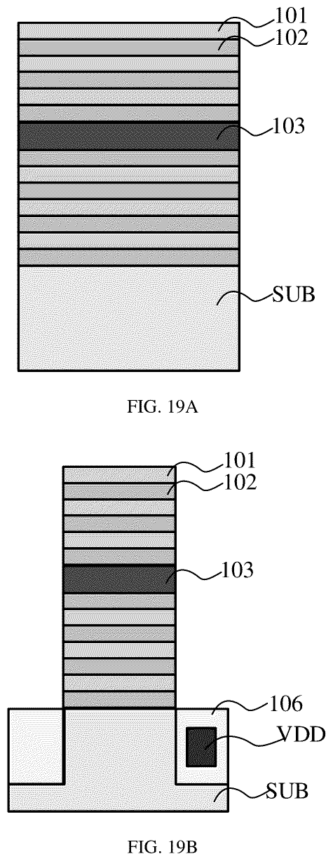

FIG. 13A, FIG. 14A, FIG. 15A, FIG. 16A, FIG. 17A, FIG. 18A, and FIG. 19A are cross-sectional views in the X-X′ axial direction in the process of manufacturing the vertical semiconductor device. FIG. 13B, FIG. 14B, FIG. 15B, FIG. 16B, FIG. 17B, FIG. 18B, and FIG. 19B are cross-sectional views in the Y4-Y4′ axial direction in the process of manufacturing the vertical semiconductor device. Referring to FIGS. 13A to 19B, a spacer 104 may be formed using the spacer imaging transfer (SIT) process. A material of the spacer 104 may be silicon nitride or the like. In embodiments of the present disclosure, a mandrel 105 may be formed on the upper stack, and the mandrel 105 may be patterned using the photolithography process to obtain a linear pattern extending in the X direction. A material of the mandrel 105 may be polycrystalline silicon or amorphous silicon, etc. The spacer 104 is formed in the above-described region, and the patterned mandrel 105 is removed after forming the spacer 104, so that only the spacer 104 remains on the stack, thus completing the manufacturing of the spacer 104. On this basis, the upper stack, the intermediate layer 103, the lower stack, and the substrate SUB are etched using the anisotropic etching process according to the pattern of the spacer 104, so as to form a fin extending in the first direction on the substrate SUB and a substrate etching region distributed on both sides of the fin in the first direction.

A dielectric material 106 is deposited in the substrate etching region. Then, according to the BPR (Buried Power Rail) pattern, the dielectric material 106 is etched to obtain a deep hole with a lower surface lower than the upper surface of the lower portion of the fin composed of the substrate SUB in the fin. A conductive material with an upper surface not higher than the upper surface of the lower portion of the fin is provided in the deep hole to form a power rail VDD. On this basis, a dielectric material is filled to seal the deep hole filled with the conductive material, and after sealing, the dielectric material 106 is etched to be lower than the upper surface of the lower portion of the fin or at the same height as the upper surface of the lower portion of the fin, so as to obtain a shallow trench isolation component. The dielectric material in embodiments of the present disclosure may include silicon dioxide or silicon nitride, etc. On this basis, referring to the buried power rails in the related art shown in FIG. 18B′, it may be seen that in the embodiment shown in FIG. 18B′, the shallow trench isolation components on both sides of the fin are embedded with the power rails. Compared with that technology, by using the above-described manufacturing method in the present disclosure, the number of buried power rails is reduced, thereby reducing the horizontal cross-sectional area of the vertically stacked semiconductor device manufactured in the present disclosure.

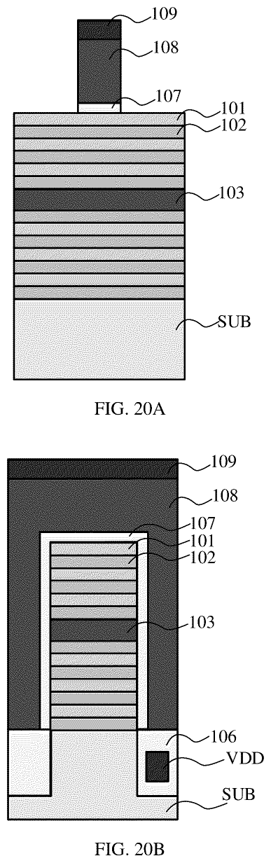

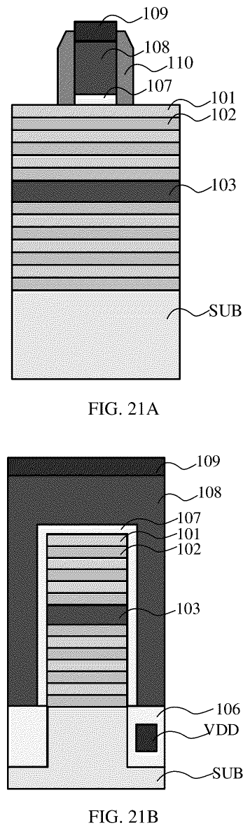

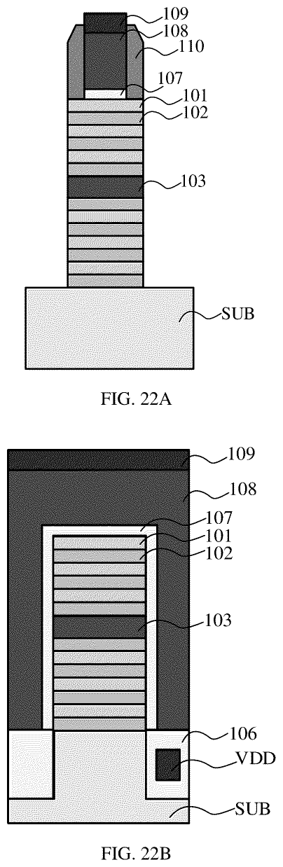

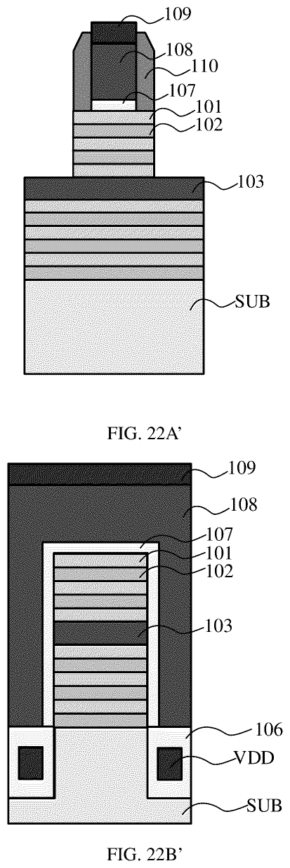

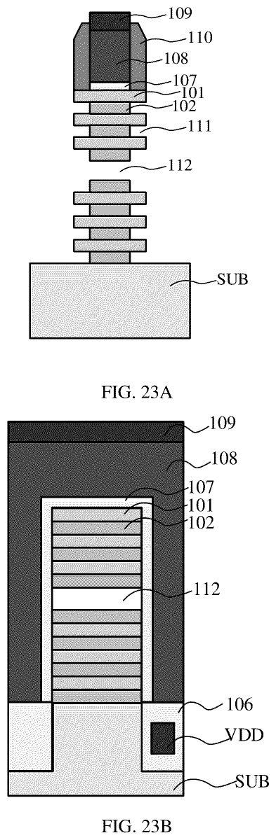

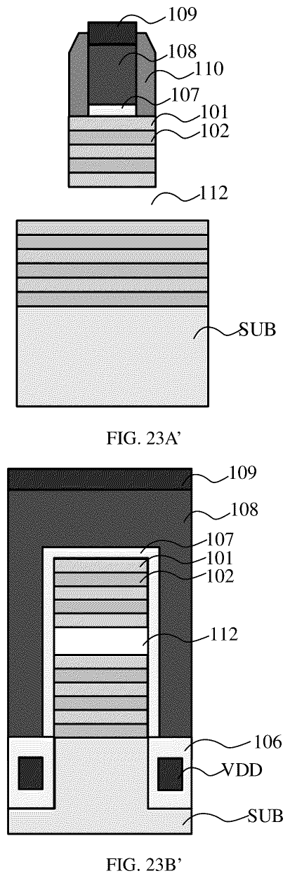

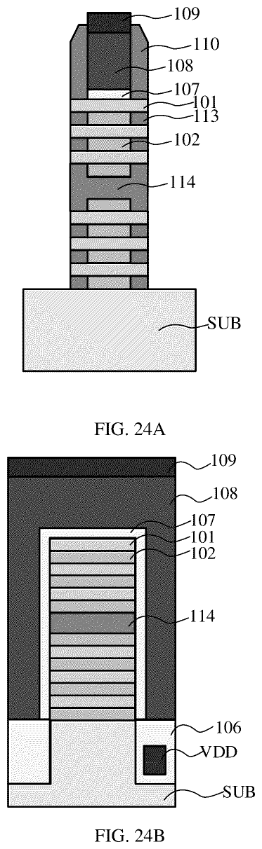

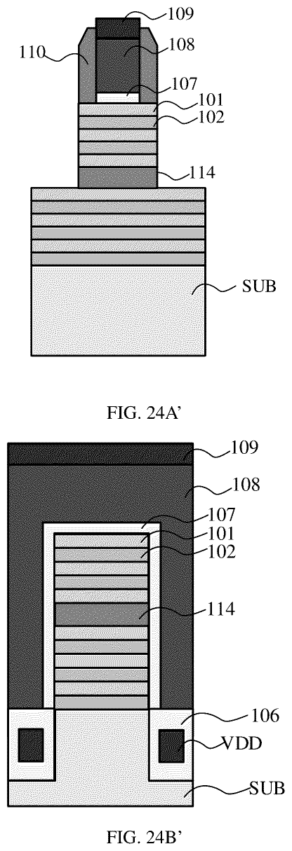

FIG. 20A, FIG. 21A, FIG. 22A, FIG. 23A, and FIG. 24A are cross-sectional views in the X-X′ axial direction in the process of manufacturing the vertical semiconductor device. FIG. 20B, FIG. 21B, FIG. 22B, FIG. 23B, and FIG. 24B are cross-sectional views in the Y4-Y4′ axial direction in the process of manufacturing the vertical semiconductor device. Referring to FIGS. 20A to 24B, a sacrificial gate across the fin may be formed on the dielectric material 106 using processes such as thermal oxidation, chemical vapor deposition, or sputtering. The sacrificial gate includes a gate oxide layer 107, a silicon layer 108, and a mask layer 109 from bottom to top. A material of the gate oxide layer 107 may be SiO₂ or the like. A material of the silicon layer 108 is amorphous silicon or polycrystalline silicon. A material of the hard mask layer 109 may be oxides, carbides, or organic compounds. On this basis, a gate spacer 110 may be formed on a sidewall of the sacrificial gate through the spacer formation process. A material of the gate spacer may be SiCNO or the like. The upper stack, the intermediate layer, and the lower stack may be etched according to the pattern of the sacrificial gate and the gate spacer 110, so that the patterned lower stack, the patterned intermediate layer, and the patterned upper stack have side surfaces exposed in the first direction.

Due to the etching selectivity of the sacrificial layer 102 and the intermediate layer 103 relative to the substrate SUB and the channel layer 101, selective etching may be performed on the sacrificial layer 102 and the intermediate layer 103 through the exposed side surfaces described above. In selective etching, the etching rate of the intermediate layer 103 is greater than that of the sacrificial layer 102, so that when selective etching is completed, the intermediate layer 103 is removed, the sacrificial layer 102 is retained, and the end portion of the retained sacrificial layer 102 in the first direction is recessed relative to the channel layer 101. In an embodiment of the present disclosure, the material type of the intermediate layer and the material type of the sacrificial layer are the same, the element doping ratio of the intermediate layer and the element doping ratio of the sacrificial layer are different, so that the etching rate of the intermediate layer is greater than that of the sacrificial layer. Based on this, synchronous etching of the intermediate layer 103 and the sacrificial layer 102 may be achieved. For example, the etching selectivity ratio between the intermediate layer 103 and the sacrificial layer 102 is greater than 5:1. For example, the material of the sacrificial layer 102 and the material of the intermediate layer 103 may both be Ge doped with SiGe. By setting the doping content of Ge in the sacrificial layer 102 to be different from that in the intermediate layer 103, the above selective etching may be achieved, and the etching rate of the intermediate layer may be greater than that of the sacrificial layer. For example, the doping content of Ge in the intermediate layer 103 is set to be greater than that in the sacrificial layer 102.

Based on this, an opening 112 is formed after etching the intermediate layer 103, and the recess of the end portion of the sacrificial layer 102 in the first horizontal direction relative to the channel layer 101 is referred to as an opening 111. The space released by the selective etching of the sacrificial layer 102 and the intermediate layer 103 in the fin is filled with a dielectric material. The portion of the dielectric material filled at the end portion of the sacrificial layer 102 is used as the inner spacer 113, and the portion of the dielectric material filled between the lower and upper stacks is used as the inter-device isolation layer 114. The inner spacer 113 in the upper stack is symmetrical to the inner spacer 113 in the lower stack. On this basis, referring to the etching method of the channel layer 101 in the related art shown in FIG. 22A′, FIG. 23A′, and FIG. 24A′, and FIG. 22B′, FIG. 23B′, and FIG. 24B′, it may be seen that in the related art, the intermediate layer 103 is completely etched off to form the opening 112, and then the upper stack is etched, and the lower stack is not etched in this step. That is, in the related art, the upper and lower stacks are etched in different steps. Compared with that technology, the above manufacturing method in the present disclosure achieves the monolithic manufacturing of the inner spacer 113 and the inter-device isolation layer 114, thereby reducing the steps of the manufacturing process, and avoiding the adverse result of misalignment of sides of the upper and lower field-effect transistors in the vertically stacked semiconductor device in the vertical direction caused by separately manufacturing the inner spacer 113 and the inter-device isolation layer 114.

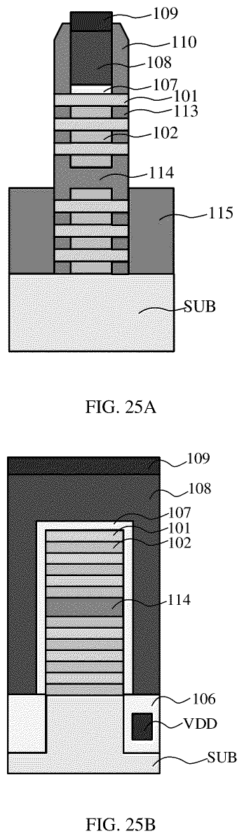

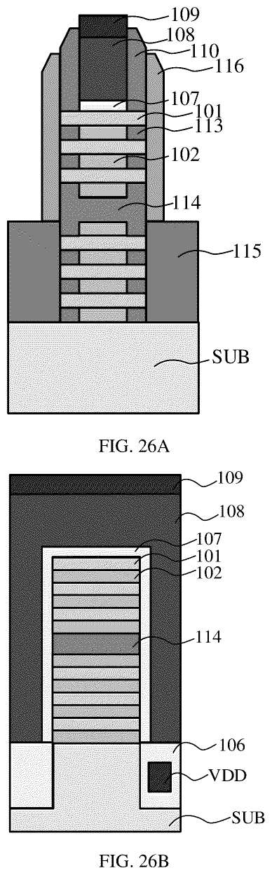

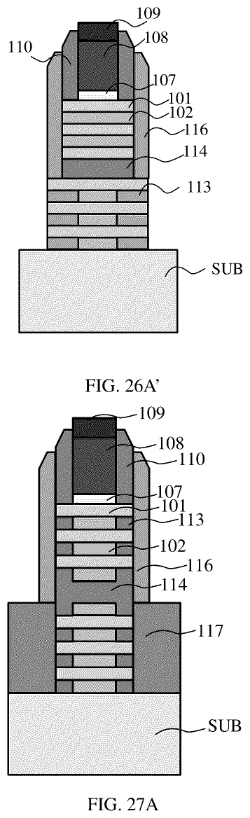

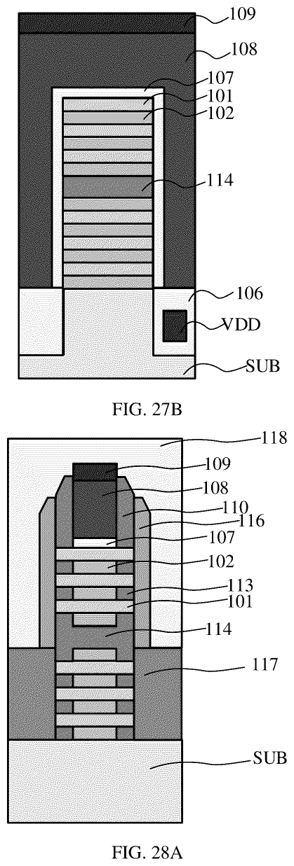

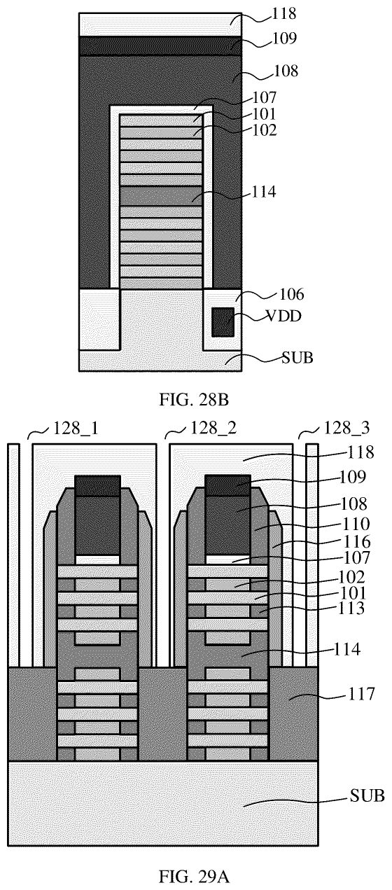

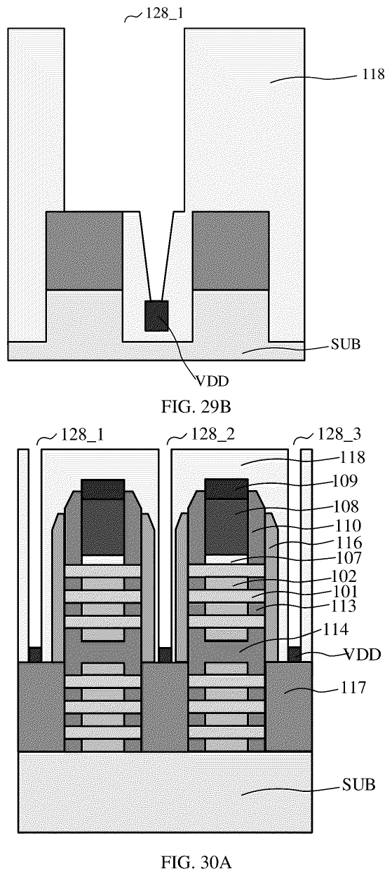

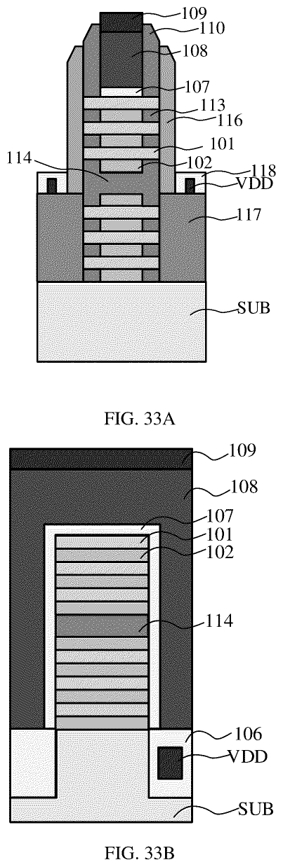

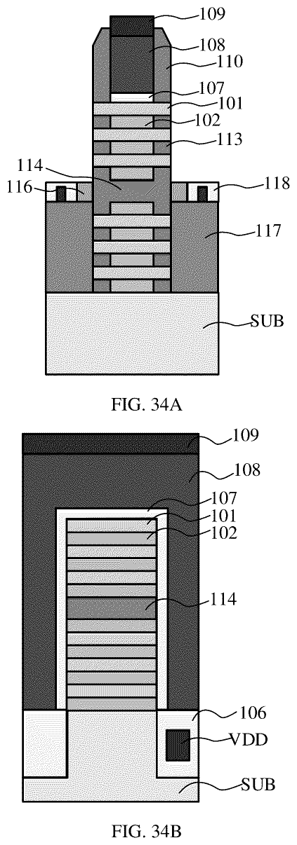

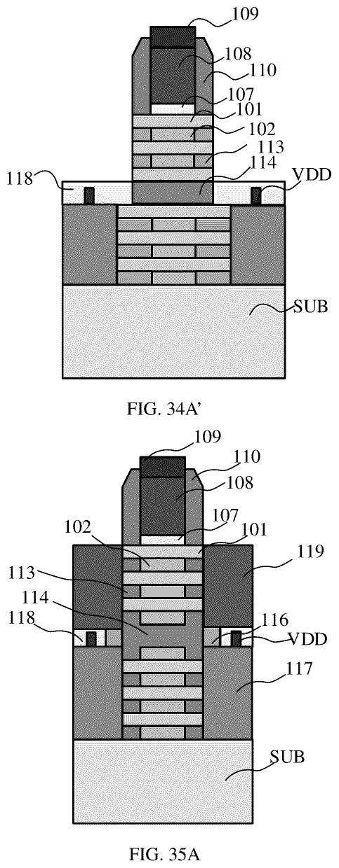

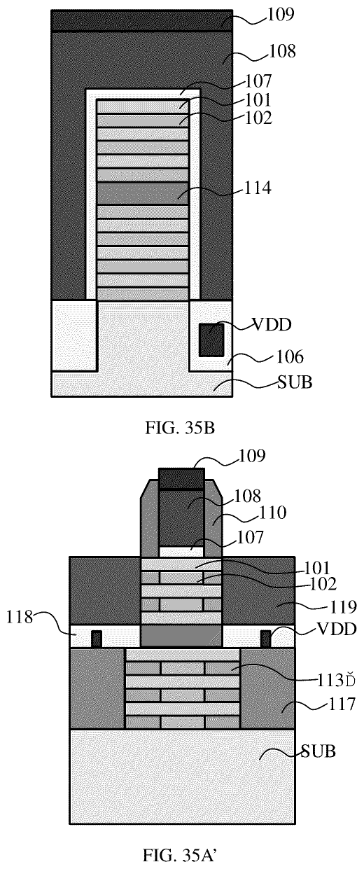

FIG. 25A, FIG. 26A, FIG. 27A, FIG. 28A, FIG. 33A, FIG. 34A, and FIG. 35A are cross-sectional views in the X-X′ axial direction in the process of manufacturing the vertical semiconductor device. FIG. 25B, FIG. 26B, FIG. 27B, FIG. 28B, FIG. 33B, FIG. 34B, and FIG. 35B are cross-sectional views in the Y4-Y4′ axial direction in the process of manufacturing the vertical semiconductor device. Referring to FIGS. 25A to 28A, 33A to 35A, 25B to 28B, and 33B to 35B, forming a lower source/drain layer 117 adjacent to an exposed side surface of the channel layer 101 in the lower stack and forming an upper source/drain layer 119 adjacent to an exposed side surface of the channel layer 101 in the upper stack includes: forming a protective spacer 116 on the substrate SUB to protect the upper stack; forming a first electrode material layer adjacent to the lower stack in an unprotected region between the protective spacer 116 and the substrate SUB; in-situ doping the first electrode material layer to obtain the lower source/drain layer 117; depositing a dielectric material on the lower source/drain layer to form the inter-device isolation layer 114 isolating the lower source/drain layer from the upper source/drain layer; removing the protective spacer 116 exposed outside the inter-device isolation layer 114; forming a second electrode material layer adjacent to the upper stack on the inter-device isolation layer 114; in-situ doping the second electrode material layer to form the upper source/drain layer 119; and activating the lower source/drain layer 117 and the upper source/drain layer 119. On this basis, referring to the setting method of the inner spacer 113 in the related art shown in FIG. 26A′, it may be seen that in the related art, when the inner spacer 113 of the lower stack is provided, the inner spacer 113 of the upper stack has not yet been formed. That is, in the embodiment shown in FIG. 26A′, the inner spacer 113 of the lower stack and the inner spacer 113 of the upper stack are formed in different steps. Compared with that embodiment, the above manufacturing method in the present disclosure achieves the monolithic manufacturing of the inner spacer 113 and the inter-device isolation layer 114, thereby reducing the steps of the manufacturing process, and avoiding the adverse result of misalignment of outer surfaces of the upper and lower field-effect transistors in the vertically stacked semiconductor device in the vertical direction caused by separately manufacturing the inner spacer 113 and the inter-device isolation layer 114. On this basis, further referring to FIG. 34A′ and 35A′, it may be seen that in the related art, as the inner spacer 113 in the upper stack and the inner spacer 113 in the lower stack are formed separately in different steps, the outer surfaces of the inner spacer 113 in the upper stack and the inner spacer 113 in the lower stack in that embodiment are not aligned in the vertical direction, which will result in the horizontal area of the upper source/drain layer 119 being greater than that of the lower source/drain layer 117. In contrast, in the vertically stacked semiconductor device of the present disclosure, as the outer surface of the inner spacer 113 in the upper stack is substantially aligned with the outer surface of the inner spacer 113 in the lower stack in the vertical direction, the horizontal cross-sectional area of the upper source/drain layer 119 is equal to the horizontal cross-sectional area of the lower source/drain layer 117 in the vertically stacked semiconductor device of the present disclosure.

For example, a lower source/drain position defining layer 115 adjacent to the channel layer 101 is formed on both sides of the channel layer 101 located below the inter-device isolation layer 114, and a protective spacer 116 is formed on the lower source/drain position defining layer 115 using a spacer formation process. A material of the lower source/drain position defining layer 115 may include but is not limited to a-C (amorphous carbon). The formation method of the lower source/drain position defining layer 115 includes but is not limited to spin coating. For example, after depositing a-C, the deposited a-C may be planarized and etched back to a position not higher than the middle of the inter-device isolation layer 114. A material of the protective spacer 116 includes but is not limited to SiNₓ, etc. The protective spacer 116 is used to protect the channel layer 101 located above the inter-device isolation layer, avoiding the growth of source/drain at both ends of the channel layer 101 of the upper device during the growth process of the source/drain of the lower device. In the case of different types of upper and lower devices, the respective source/drain materials of upper and lower devices may be different.

After forming the protective spacer 116, the lower source/drain position defining layer 115 is removed to expose the sidewall of the channel layer 101 located below the inter-device isolation layer 114. On the exposed sidewall of the channel layer 101, a source/drain material layer is epitaxially grown and in-situ doped to form a lower source/drain layer 117 adjacent to the lower stack. The source/drain material may be SiGe or Si. A dielectric material 118 may be deposited on the lower source/drain layer 117 and etched to a position not higher than the inter-device isolation layer 114, so as to electrically isolate the respective source/drain layers of the upper and lower devices. The protective spacer 116 may be selectively etched to expose the sidewall of the channel layer 101 located above the inter-device isolation layer 114. On the exposed sidewall of the channel layer 101, a source/drain material is epitaxially grown and in-situ doped to form a source/drain layer 119 adjacent to the upper stack. On this basis, source/drain activation is performed on the source/drain layers 117 and 119 to obtain the activated source/drain layers 117 and 119.

In embodiments of the present disclosure, a shallow trench isolation component is provided next to the upper portion of the substrate SUB. The shallow trench isolation component is pre-embedded with a power rail VDD for electrically connecting to the power supply. After depositing the dielectric material 118, the above manufacturing method further includes: etching the shallow trench isolation component according to a position of the lower source layer and a position of the power rail VDD, so as to form an isolation component opening that exposes the lower source layer and the power rail VDD; and filling the isolation component opening with a conductive material, and sealing the isolation component opening with a dielectric material after filling the conductive material, so as to form a contact hole for electrically connecting the lower source layer to the power rail.

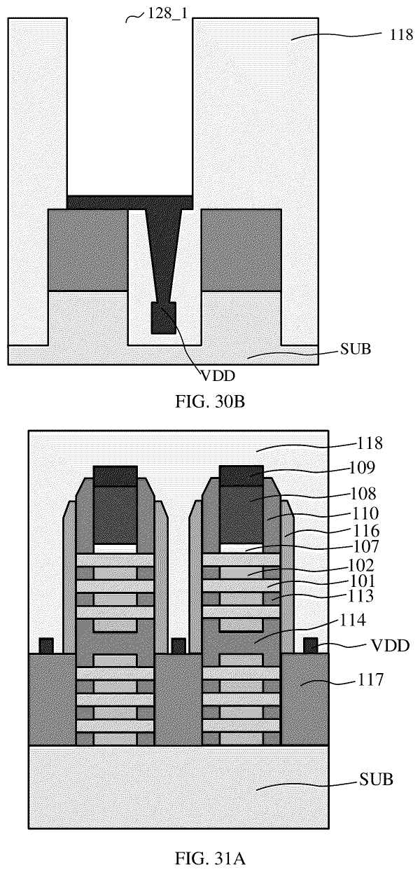

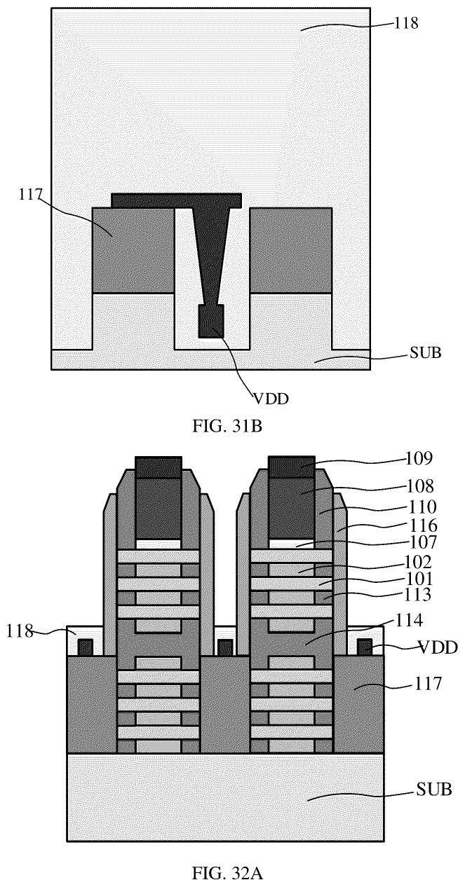

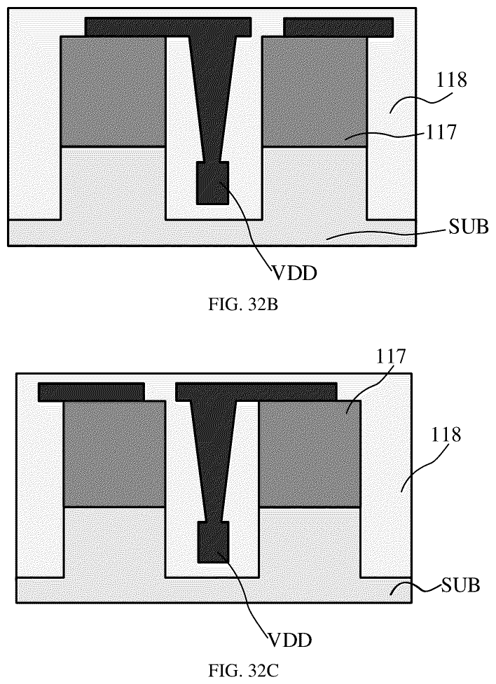

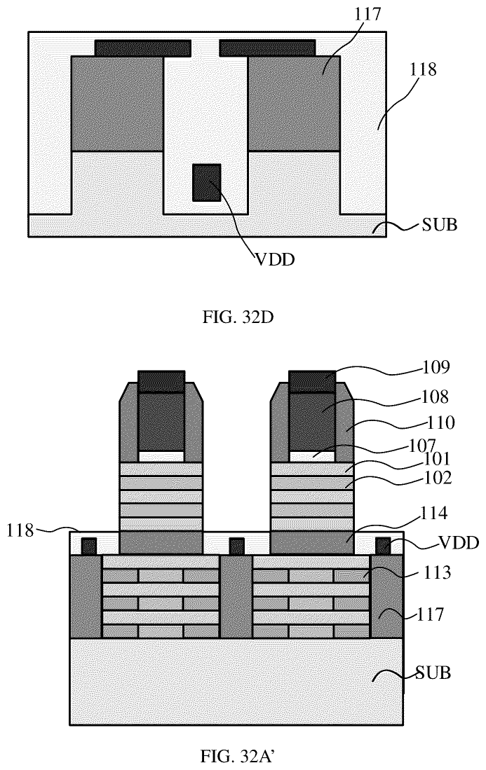

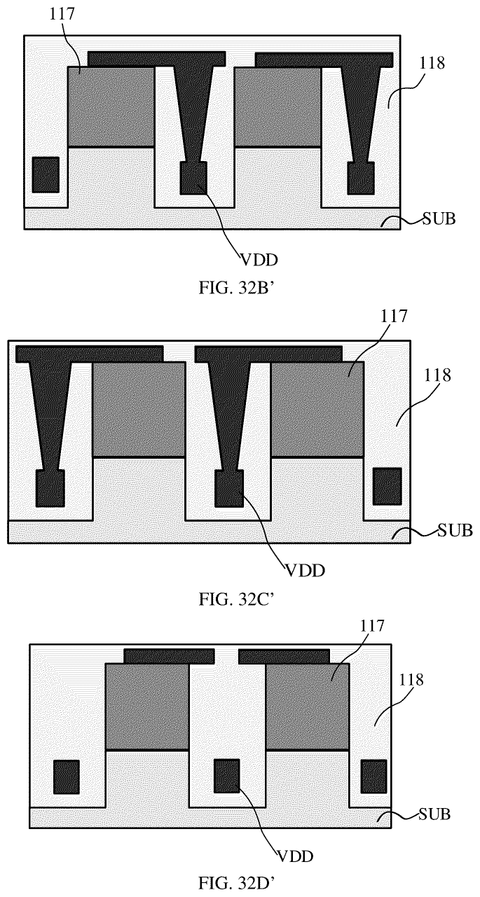

For example, taking the four field-effect transistors in the first group of field-effect transistors and the four field-effect transistors in the second group of field-effect transistors as examples, FIG. 29A, FIG. 30A, FIG. 31A and FIG. 32A are cross-sectional views in the X-X′ axial direction in the process of manufacturing the vertical semiconductor device. FIG. 29B, FIG. 30B, FIG. 31B and FIG. 32B are cross-sectional views in the Y2-Y2′ axial direction in the process of manufacturing the vertical semiconductor device. FIG. 32C is a cross-sectional view in the Y1-Y1′ axial direction in the process of manufacturing the vertical semiconductor device. FIG. 32D is a cross-sectional view in the Y3-Y3′ axial direction in the process of manufacturing the vertical semiconductor device.

On this basis, FIGS. 29A to 32A, 29B to 32B, 32C, and 32D show schematic cross-sectional diagrams of the structure integrated with the above eight field-effect transistors.

Referring to FIGS. 29A to 32A, 29B to 32B, 32C, and 32D, after depositing the dielectric material 118 on the lower source/drain layer 117 and etching the dielectric material 118 to a position not higher than the inter-device isolation layer 114, the manufacturing method further includes: etching the dielectric material 118 and the dielectric material 106 according to the position of the lower source/drain layer 117, so as to form isolation component openings 128_1, 128_2, and 128_3. Each of the isolation component openings 128_1, 128_2, and 128_3 exposes the power rail and the lower source/drain layer. A conductive material is deposited in the isolation component openings 128_1, 128_2, and 128_3. On this basis, a contact hole for electrically connecting the lower source layer to the power rail is formed based on the conductive material in the isolation component openings 128_1 and 128_3. Based on the conductive material in the isolation component opening 128_2, a contact hole is formed for contact with the lower drain layer in the first group of field-effect transistors or the lower drain layer in the second group of field-effect transistors. On this basis, referring to the power rails VDD in the related art shown in FIG. 32A′, 32B′, 32C′, and 32D′, it may be seen that the number of power rails VDD in this embodiment is greater than that of the power rails VDD in the present disclosure. As a result, the manufacturing method of the present disclosure reduces the horizontal cross-sectional area of the semiconductor device, making the horizontal cross-sectional area of the vertically stacked semiconductor device of the present disclosure less than that of the semiconductor device in the related art.

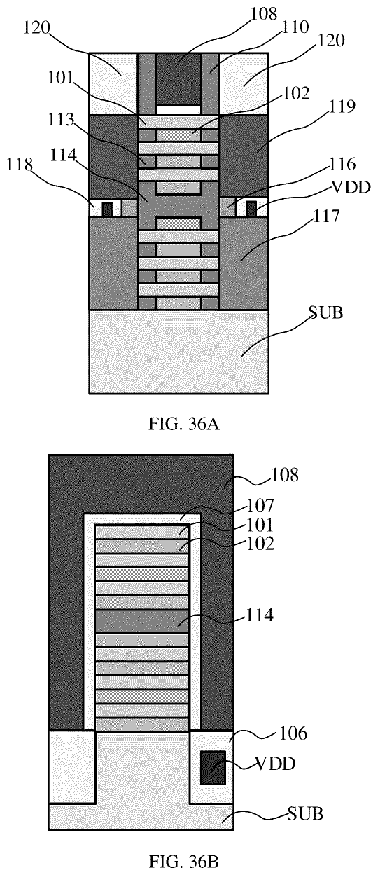

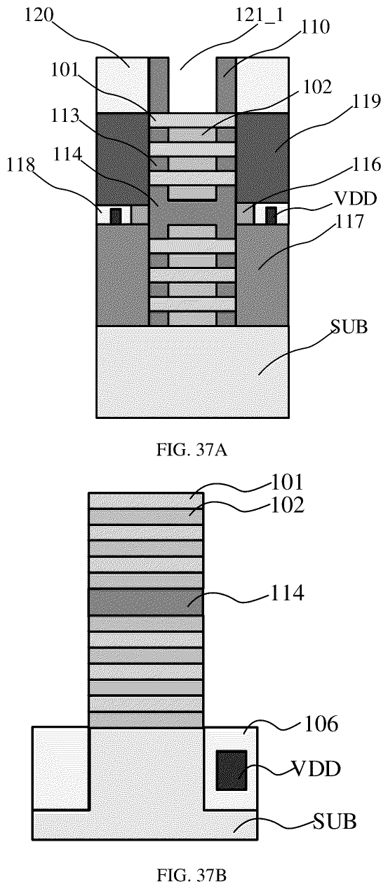

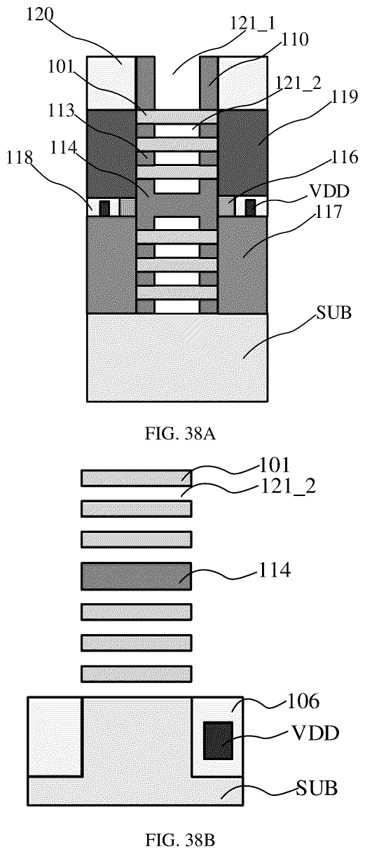

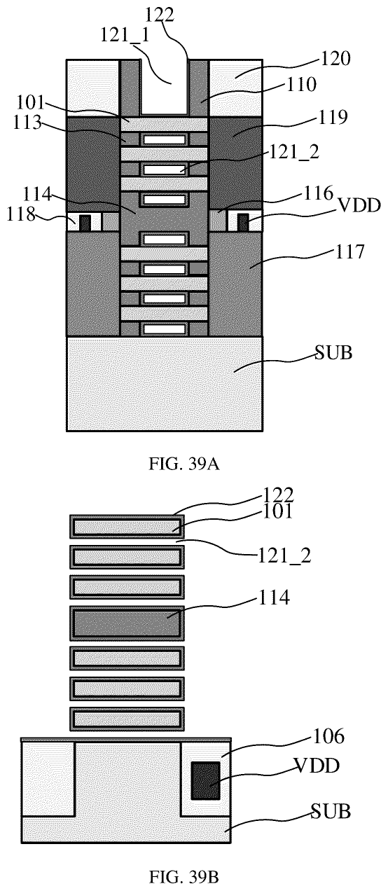

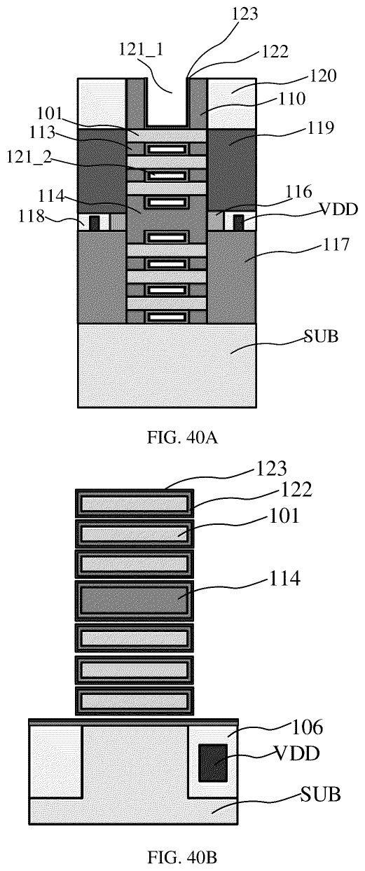

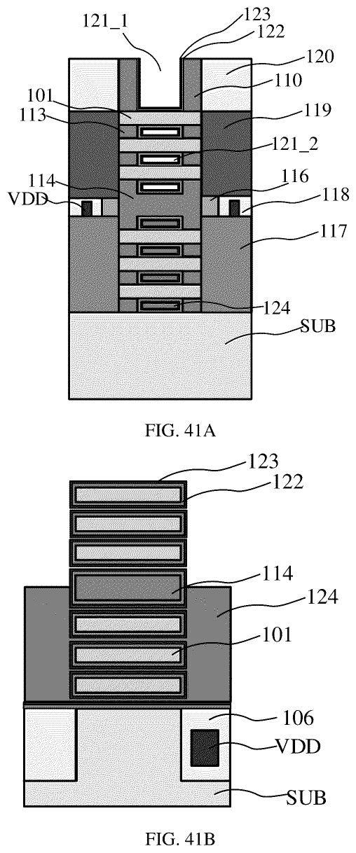

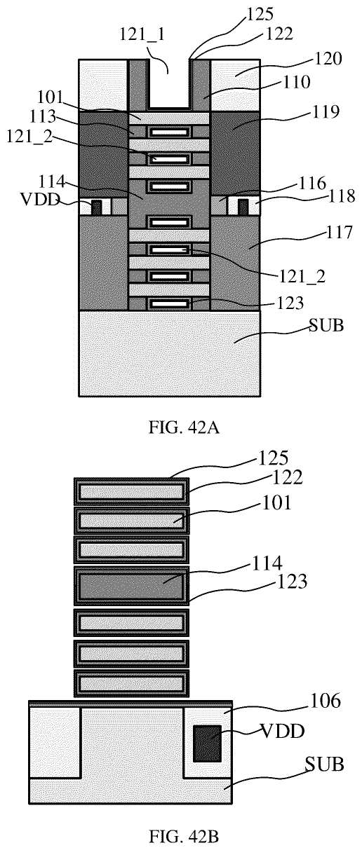

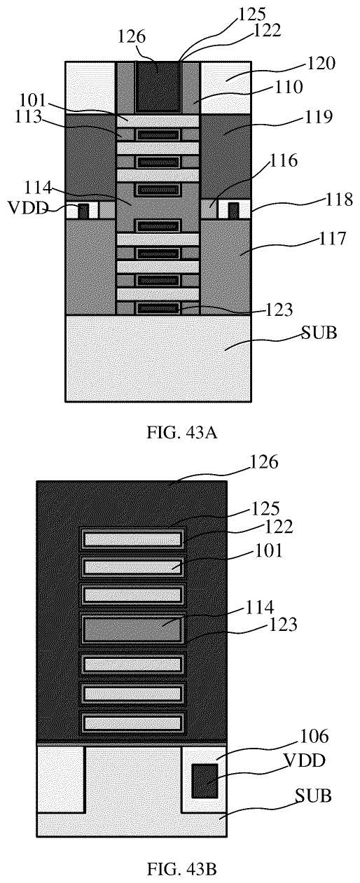

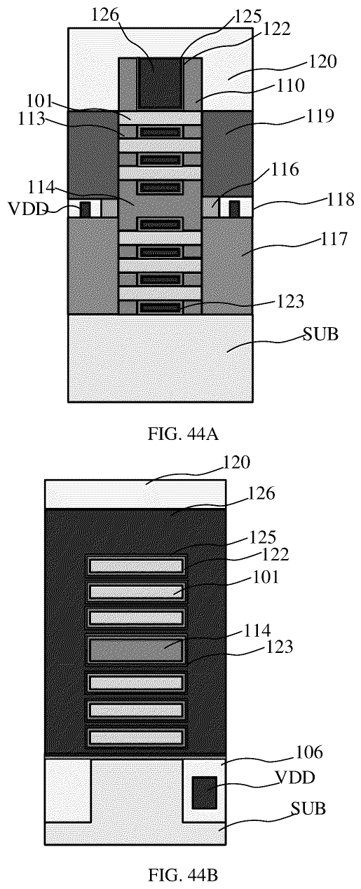

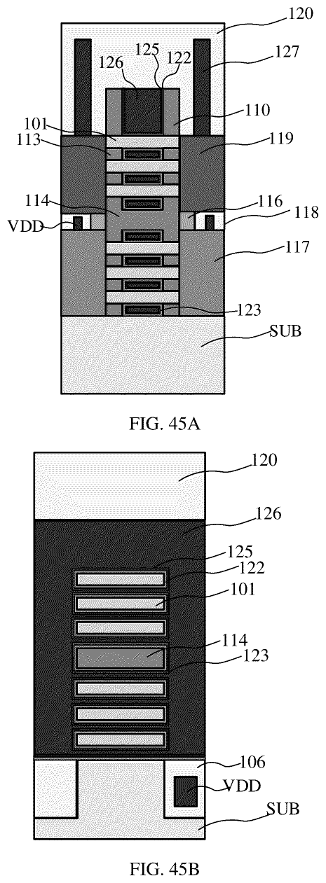

FIG. 36A, FIG. 37A, FIG. 38A, FIG. 39A, FIG. 40A, FIG. 41A, FIG. 42A, FIG. 43A, and FIG. 44A are cross-sectional views in the X-X′ axial direction in the process of manufacturing the vertical semiconductor device. FIG. 36B, FIG. 37B, FIG. 38B, FIG. 39B, FIG. 40B, FIG. 41B, FIG. 42B FIG. 43B, and FIG. 44B are cross-sectional views in the Y4-Y4′ axial direction in the process of manufacturing the vertical semiconductor device. Referring to FIGS. 36A to 44A, and 36B to 44B, a dielectric material 120 is formed on the substrate SUB, and the dielectric material 120 is planarized to remove the mask layer 109 in the sacrificial gate and expose the silicon layer 108. The dielectric material 120, the gate spacer 110, and the silicon layer 108 are etched to have same heights. Then, the silicon layer 108 and the sacrificial layer 102 are etched using the etching back process, so that on the inner side of the gate spacer 110 and the inner spacer 113, a cavity 121_1 exposed by etching is formed at the original position of the silicon layer 108, and a cavity 121_2 exposed by etching is formed at the original position of the sacrificial layer 102.

A gate stack surrounding the channel layer 101 is formed on the inner sidewalls of cavities 121_1 and 121_2. The gate stack includes a gate dielectric layer 122 and a P-type work function layer 123. A material of the gate dielectric layer 122 may be a high-K dielectric material, where K represents the dielectric constant. High k dielectric materials include one or more of HfO₂, HfSiOₓ, HfON, HfSiON, HfAlOₓ, HfLaOₓ, Al₂O₃, ZrO₂, ZrSiOₓ, Ta₂O₅, or La₂O₃. A material of the P-type work function layer 123 may be titanium nitride or the like. A protective layer 124 is formed on the substrate SUB. The protective layer 124 is etched so that a top surface of the protective layer 124 is located between the top and bottom surfaces of the inter-device isolation layer 114, so as to shield the cavity for the lower devices. In this way, the protective layer 124 protects the P-type work function layer 123 located in the cavity below the inter-device isolation layer 114, while the P-type work function layer 123 located in the cavity above the inter-device isolation layer 114 is exposed.

The P-type work function layer 123 located above the inter-device isolation layer 114 is etched using a selective etching process, and the gate dielectric layer 122 located above the inter-device isolation layer 114 is retained. Then, an N-type work function layer 125 is formed to surround the gate dielectric layer 122 located above the inter-device isolation layer 114. Therefore, different gate stacks surrounding the channel layers 101 are formed above and below the inter-device isolation layer 114. Therefore, the channel layer 101, the gate stack, and the source/drain layer 119 located above the inter-device isolation layer 114 constitute an N-type field-effect transistor, while the channel layer 101, the gate stack, and the source/drain layer 117 located below the inter-device isolation layer 114 constitute a P-type field-effect transistor, thereby obtaining stacked field-effect transistors.

It should be understood that the above is only one embodiment of the present disclosure. In the manufacturing process in other embodiments of the present disclosure, N-type field-effect transistors or P-type field-effect transistors may be formed as desire by changing the doping type of the source/drain layers and forming corresponding types of work function layers. For example, the upper N-type field-effect transistors may be changed to P-type field-effect transistors, and/or the lower P-type field-effect transistors may be changed to N-type field-effect transistors.

After manufacturing the above-described N-type field-effect transistor and P-type field-effect transistor, the protective layer 124 is removed to release a cavity located below the inter-device isolation layer 114. Then, a conductive material is deposited in all cavities 121_1 and 121_2 to form a conductive layer 126, thereby completing the manufacturing of the gate structure. The conductive material in embodiments of the present disclosure may include tungsten and/or the like. After forming the conductive layer 126, the conductive layer 126 may be planarized, and a dielectric material may be deposited on the planarized conductive layer 126.

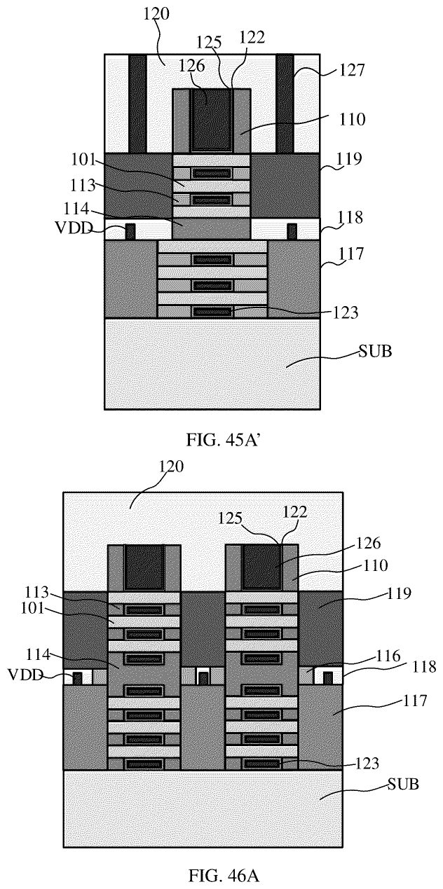

FIG. 45A is a cross-sectional view in the X-X′ axial direction in the process of manufacturing the vertical semiconductor device. FIG. 45B is a cross-sectional view in the Y4-Y4′ axial direction in the process of manufacturing the vertical semiconductor device. Referring to FIGS. 45A and 45B, a contact hole 127 in contact with the source/drain layer 119 may be formed in the dielectric material 120. On this basis, referring to FIG. 45A′, it may be seen that in the related art, the inter-device isolation layer 114 is in close contact with the channel layer 101 adjacent to the inter-device isolation layer 114, so the gate stack is not provided between the inter-device isolation layer 114 and the channel layer 101 adjacent to the inter-device isolation layer 114. In the vertical semiconductor device of the present disclosure, the gate stack includes a portion located below a lower surface of a bottommost channel layer 101 among the plurality of channel layers 101 in the upper stack, and a portion located on an upper surface of a topmost channel layer 101 among the plurality of channel layers 101 in the lower stack. Therefore, the manufacturing method of the present disclosure enables the gate stack to more comprehensively surround the channel layers 101, thereby improving the performance of the manufactured semiconductor device.

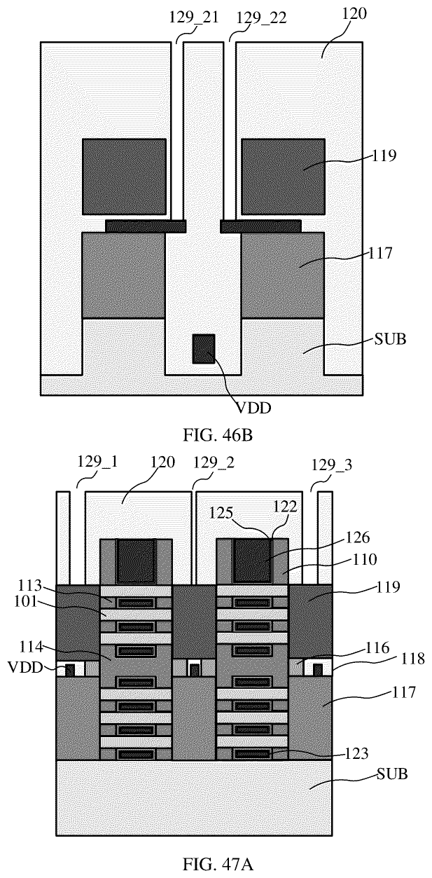

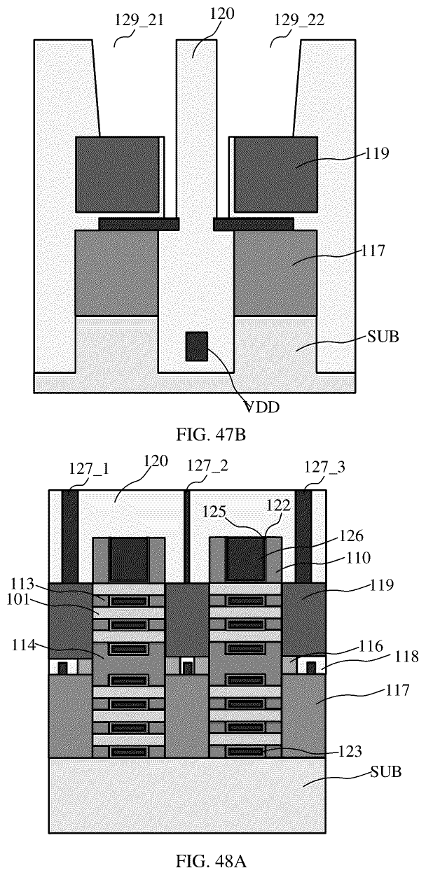

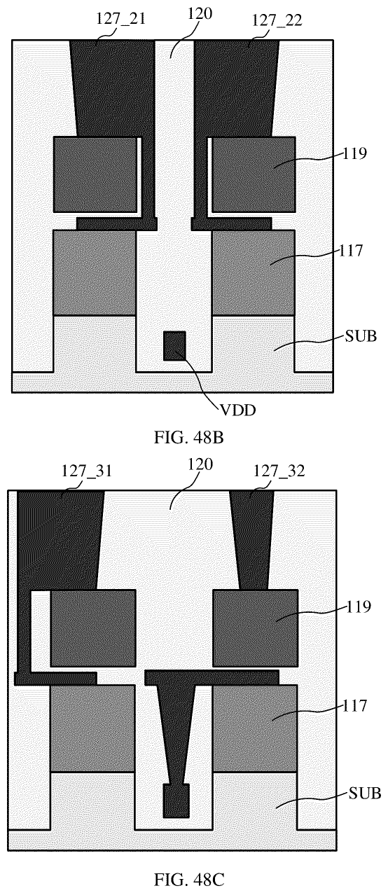

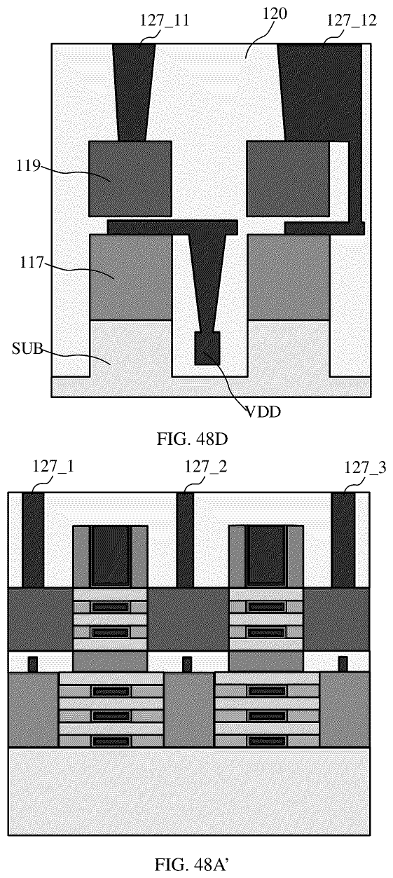

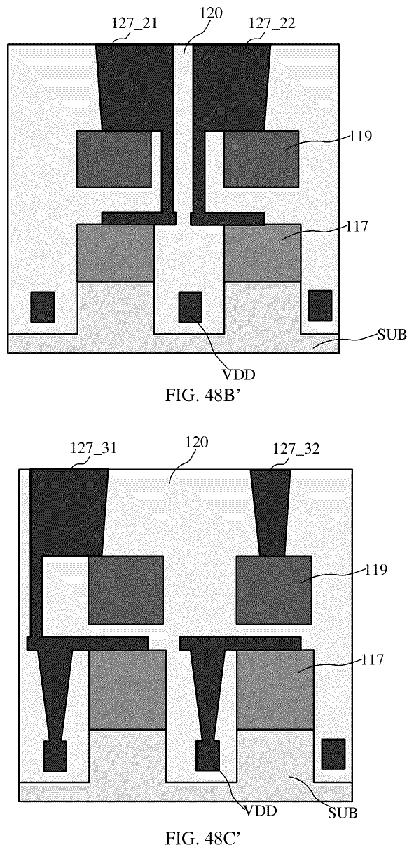

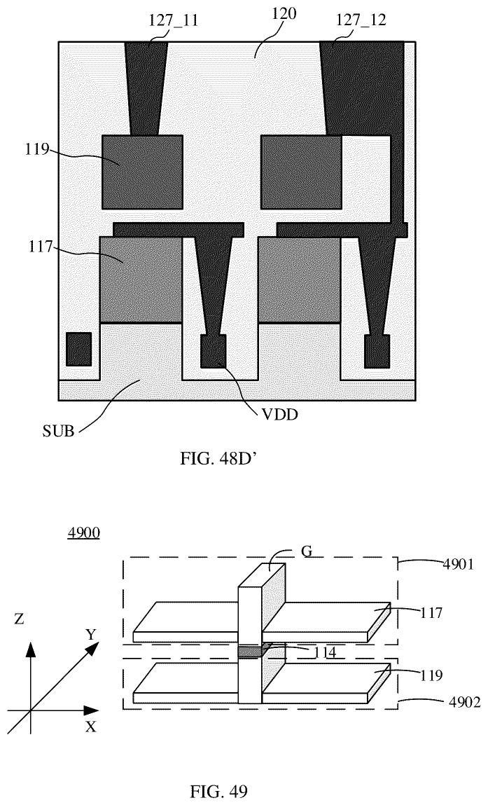

For example, taking the four field-effect transistors in the first group of field-effect transistors and the four field-effect transistors in the second group of field-effect transistors as examples, FIG. 46A, FIG. 47A, and FIG. 48A are cross-sectional views in the X-X′ axial direction in the process of manufacturing the vertical semiconductor device. FIG. 46B, FIG. 47B, and FIG. 48B are cross-sectional views in the Y3-Y3′ axial direction in the process of manufacturing the vertical semiconductor device. FIG. 48C is a cross-sectional view in the Y1-Y1′ axial direction in the process of manufacturing the vertical semiconductor device. FIG. 48D is a cross-sectional view in the Y2-Y2′ axial direction in the process of manufacturing the vertical semiconductor device.

On this basis, FIGS. 46A to 48D show schematic cross-sectional diagrams of the structure integrated with the above eight field-effect transistors. Referring to FIGS. 46A to 48D, the above manufacturing method further includes: forming an intermediate dielectric layer covering the upper stack, the upper source/drain layer, and the lower source/drain layer, where the intermediate dielectric layer may include the above-described dielectric material 120, the above-described dielectric material 118, and the above-described dielectric material 120; etching the intermediate dielectric layer to form a dielectric layer opening exposing the upper source/drain layer and the lower source/drain layer; and providing a conductive material in the dielectric layer opening to form a contact hole, where the contact hole in the intermediate dielectric layer allows an upper drain layer and a lower drain layer to be electrically connected to a data output terminal through the contact hole, and the contact hole in the intermediate dielectric layer also allows: a non-powered lower source layer that is not electrically connected to a power supply to be electrically connected to a ground terminal, and an upper source layer located directly above the non-powered lower source layer to be electrically connected to the ground terminal; or an upper source layer located directly above a powered lower source layer electrically connected to the power supply to be electrically connected to a bit line terminal.

For example, on the upper surface of the dielectric material 120, the dielectric material 120 is etched until the source/drain layer 119 is exposed, so as to form dielectric layer openings 129_1, 129_2, and 129_3 located in the dielectric material 120. The conductive material in contact with the lower drain layer of the first group of field-effect transistors is exposed at the dielectric layer opening 129_21 in the Y3-Y3′ axial direction, and the conductive material in contact with the lower drain layer of the second group of field-effect transistors is exposed at the dielectric layer opening 129_22. On this basis, the dielectric layer opening 129_21 is further etched to expose both the conductive material in contact with the lower drain layer of the first group of field-effect transistors and the upper drain layer located on the lower drain layer. Furthermore, the dielectric layer opening 129_22 is further etched to expose the conductive material in contact with the lower drain layer of the second group of field-effect transistors and the upper drain layer located on the lower drain layer. Based on this, the dielectric layer opening 129_21 is filled with a conductive material to form a contact hole 127_21 that contacts the lower and upper drain layers of the first group of field-effect transistors. The dielectric layer opening 129_22 is filled with a conductive material to form a contact hole 127_22 that contacts the lower and upper drain layers of the second group of field-effect transistors. The contact hole 127_21 may be electrically connected to the first data output terminal, and the contact hole 127_22 may be electrically connected to the second data output terminal.

Similarly, the dielectric layer opening 129_1 includes a dielectric layer opening 129_11 and a dielectric layer opening 129_12. The conductive material in contact with the lower source layer of the second group of field-effect transistors is exposed at the dielectric layer opening 129_11 in the Y2-Y2′ axial direction, and the lower and upper source layers of the first group of field-effect transistors are exposed at the dielectric layer opening 129_12 in the Y2-Y2′ axial direction. Based on this, the dielectric layer opening 129_11 is filled with a conductive material to form a contact hole 127_11; and the dielectric layer opening 129_12 is filled with a conductive material to form a contact hole 127_12. The contact hole 127_11 may be electrically connected to the first bit line terminal, and the contact hole 127_12 may be electrically connected to the ground terminal.

Similarly, the dielectric layer opening 129_3 includes a dielectric layer opening 129_31 and a dielectric layer opening 129_32. The lower and upper source layers of the first group of field-effect transistors are exposed at the dielectric layer opening 129_31 in the Y1-Y1′ axial direction, and the conductive material in contact with the lower source layer of the second group of field-effect transistors is exposed at the dielectric layer opening 129_32 in the Y1-Y1′ axial direction. Based on this, the dielectric layer opening 129_31 is filled with a conductive material to form a contact hole 127_31, and the dielectric layer opening 129_32 is filled with a conductive material to form a contact hole 127_32. The contact hole 127_31 may be electrically connected to the ground terminal, and the contact hole 127_32 may be electrically connected to the second bit line terminal complementary to the first bit line terminal. As a result, the vertically stacked semiconductor device of the present disclosure may be manufactured. On this basis, referring to FIG. 48A′, 48B′, 48C′, and 48D′, it may be seen that the number of power rails VDD in the semiconductor devices in the related art is greater than that in the vertically stacked semiconductor device of the present disclosure, and the number of contact holes in contact with the power rails VDD in the related art is greater than that in the vertically stacked semiconductor device of the present disclosure. As a result, the manufacturing method of the present disclosure reduces the horizontal cross-sectional area of the vertically stacked semiconductor device, making the horizontal cross-sectional area of the vertically stacked semiconductor device of the present disclosure less than that of semiconductor devices in the related art.

Based on this, in the present disclosure, the intermediate layer 103 and the sacrificial layer 102 with etching selectivity relative to the substrate SUB and the channel layer 101 are provided in the fin, and the etching rate of the intermediate layer 103 is set to be greater than that of the sacrificial layer 102. Based on this, selective etching is simultaneously performed on the intermediate layer 103 and the sacrificial layer 102. When the selective etching is completed, the intermediate layer 103 is removed while the sacrificial layer 102 is retained, and the end portion of the retained sacrificial layer 102 in the first direction is recessed relative to the channel layer 101. The space released by selective etching of the sacrificial layer 102 and the intermediate layer 103 in the fin is filled with a dielectric material, so as to form the inter-device isolation layer 114 and the inner spacer 113, achieving the monolithic manufacturing of the inter-device isolation layer 114 and the inner spacer 113, reducing process steps, and avoiding the formation of the inter-device isolation layer 114 and the inner spacer 113 in multiple sequential steps. On this basis, in the vertically stacked semiconductor device manufactured by the monolithic manufacturing method of the inter-device isolation layer 114 and the inner spacer 113, the upper source/drain layer 119 of the field-effect transistor located above and the lower source/drain layer 117 of the field-effect transistor located below are symmetrical, avoiding the adverse result of the volume of the field-effect transistor structure located above being greater than that of the field-effect transistor structure located below in sequential manufacturing. It should be understood that in embodiments of the present disclosure, the dielectric material includes but is not limited to SiO₂, SiNₓ, SiNO, SiCO, SiCNO, SiCN, polymer, a-C, and a combination thereof. The methods of filling the dielectric include but are not limited to ALD (Atomic Layer Deposition), CVD (Chemical Vapor Deposition), Spin (Rotation), and the like. Furthermore, the etching methods include but are not limited to wet etching, RIE (Reactive Ion Etching), RPS (Remote Plasma Source) etching, chemical dry etching, ALE (Atomic Layer Etching), etc. The present disclosure does not limit this, as long as the above-described manufacturing method may be implemented.

FIG. 49 shows a schematic diagram of a vertically stacked semiconductor device according to an embodiment of the present disclosure.

As shown in FIG. 49, a vertically stacked semiconductor device 4900 in this embodiment includes: a first field-effect transistor 4901 and a second field-effect transistor 4902 stacked in a vertical direction on a substrate SUB; and an inter-device isolation layer 114 between the first field-effect transistor and the second field-effect transistor, where each of the first field-effect transistor and the second field-effect transistor includes: a plurality of channel layers 101 stacked spaced apart from each other in the vertical direction; source/drain layers adjacent to the channel layers 101 on both sides of the plurality of channel layers 101 in a first direction; a gate stack extending in a second direction intersecting the first direction and surrounding the channel layers 101; and an inner spacer 113 between the gate stack and the source/drain layers, where an outer surface of the inner spacer 113 of the first field-effect transistor is substantially aligned with an outer surface of the inner spacer 113 of the second field-effect transistor. In embodiments of the present disclosure, the first field-effect transistor 4901 and the second field-effect transistor 4902 correspond to the field-effect transistor composed of the upper stack and the field-effect transistor composed of the lower stack, respectively. The source/drain layer of the first field-effect transistor 4901 is the source/drain layer 119 adjacent to the upper stack. The source/drain layer of the second field-effect transistor 4902 is the source/drain layer 117 adjacent to the lower stack. The gate stack surrounding the channel layers 101 corresponds to the gate structure G shown in FIG. 49 (the channel layers 101 are surrounded by the gate structure G and not shown in the perspective view of FIG. 49).

According to embodiments of the present disclosure, as the inter-device isolation layer 114 and the adjacent inner spacer 113 are manufactured at the same time, in the vertically stacked semiconductor device in embodiments of the present disclosure, the inter-device isolation layer 114 is integrated with the adjacent inner spacer 113.

According to embodiments of the present disclosure, in the first field-effect transistor, the gate stack includes a portion on an upper surface of a topmost channel layer 101 among the plurality of channel layers 101 in the first field-effect transistor; and in the second field-effect transistor, the gate stack includes a portion on a lower surface of a bottommost channel layer 101 among the plurality of channel layers 101 in the second field-effect transistor. Therefore, in the manufacturing method of the present disclosure, the gate stack may more comprehensively surround the channel layers 101, thereby improving the performance of the obtained semiconductor device.

According to embodiments of the present disclosure, a plurality of groups of vertically stacked field-effect transistors are provided, each group of vertically stacked field-effect transistors includes the first field-effect transistor and the second field-effect transistor stacked vertically, two groups of vertically stacked field-effect transistors among the plurality of groups of vertically stacked field-effect transistors form an inverter structure, and a plurality of inverter structures in the vertically stacked semiconductor devices are cross coupled with each other to form an SRAM structure.

According to embodiments of the present disclosure, for the two groups of vertically stacked field-effect transistors used to form the inverter structure, drain layers of the two groups of vertically stacked field-effect transistors are shared, and the shared drain layers are electrically connected to a signal output terminal. Among the two groups of vertically stacked field-effect transistors, two source layers of one group of vertically stacked field-effect transistors are electrically connected to a ground terminal, and two source layers of the other group of vertically stacked field-effect transistors are electrically connected to a bit line terminal and a power rail, respectively.

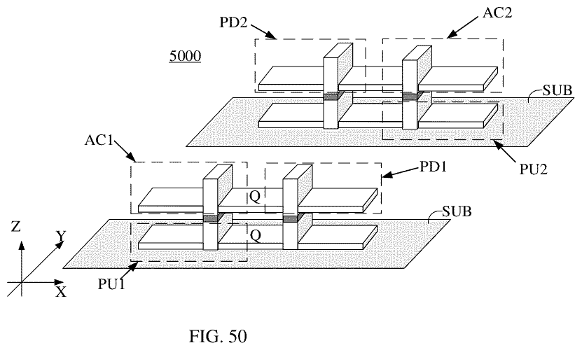

For example, the structure of the vertically stacked semiconductor device in the present disclosure will be illustrated using FIG. 50 as an example. FIG. 50 shows a schematic diagram of an SRAM structure implemented based on a vertically stacked semiconductor device according to an embodiment of the present disclosure. It should be noted that in FIG. 50, the extension direction of the X-axial direction is defined as the first direction, the extension direction of the Y-axial direction is defined as the second direction intersecting the first direction, and the extension direction of the Z-axial direction is defined as the vertical direction. In an embodiment of the present disclosure, the first direction and the second direction may be perpendicular to each other within the same horizontal plane. The vertical direction may be the direction perpendicular to the horizontal plane.

As shown in FIG. 50, an SRAM structure 5000 in this embodiment includes:
the first group of field-effect transistors in the first direction and the second group of field-effect transistors in the first direction on an upper surface of a substrate SUB; and an intermediate dielectric layer surrounding the substrate SUB, the first group of field-effect transistors, and the second group of field-effect transistors.

Each field-effect transistor shown in FIG. 50 may be used as a transmission transistor or a pull transistor according to actual desires. The transmission transistor may be a transistor used to transmit written data from the bit line. The pull transistor may include a pull-up transistor and a pull-down transistor. The pull-up transistor may be a transistor used to pull-up the node level. The pull-down transistor may be a transistor used to pull-down the node level. Moreover, the schematic diagram of the intermediate dielectric layer is omitted in FIG. 50 to avoid obscuring the SRAM structure 5000. It should be understood that the intermediate dielectric layer in embodiments of the present disclosure may be provided in the SRAM structure 5000 according to actual desires.

Continuing with reference to FIG. 50, two substrates SUB arranged in the second horizontal direction are shown in FIG. 50. A plurality of field-effect transistors integrated into an integrated structure are provided on each of the two substrates SUB. On this basis, for ease of description, in the present disclosure, the plurality of field-effect transistors located on the substrate SUB in the lower left corner of FIG. 50 are defined as the first group of field-effect transistors described above, and they are defined to be located in the front part of the space shown in FIG. 50. The transistors located on the substrate in the upper right corner of FIG. 50 are defined as the second group of field-effect transistors described above, and they are defined to be located in the rear part of the space shown in FIG. 50.

In the following, the field-effect transistor shown in FIG. 50 is defined as a pull transistor or a transmission transistor for the purpose of understanding the SRAM structure 5000 in embodiments of the present disclosure. It should be understood that the following is only an example, and those skilled in the art may set the functionality of field-effect transistors in the SRAM structure 5000 as needed.

For example, the transistor located in the upper left corner of the first group of field-effect transistors is defined as the transmission transistor AC1; the transistor located in the lower left corner of the first group of field-effect transistors is defined as the pull-up transistor PU1; and the transistor located in the upper right corner of the first group of field-effect transistors is defined as the pull-down transistor PD1. Referring to FIG. 50, the transmission transistor AC1 is coupled with the pull-down transistor PD1 through a common layer. Moreover, based on the above content, the upper common layer and the lower common layer in the first group of field-effect transistors are coupled through a connection structure. Based on this, the electrical connection between the transmission transistor AC1, the pull-up transistor PU1, and the pull-down transistor PD1 may be achieved. In addition, the common layers used for electrical connection between the transmission transistor AC1, the pull-up transistor PU1, and the pull-down transistor PD1 correspond to the first source/drain layers of the transmission transistor AC1, the pull-up transistor PU1, and the pull-down transistor PD1. The transmission transistor AC1 may be electrically connected to the bit line terminal through a source layer contact hole in contact with the second source/drain layer located on the other side of the gate structure of the transmission transistor AC1, and the transmission transistor AC1 may be electrically connected to the word line terminal through a gate contact hole in contact with its gate structure G. The pull-up transistor PU1 may be electrically connected to the power supply terminal through a source layer contact hole in contact with the second source/drain layer located on the other side of the gate structure of the pull-up transistor PU1. The pull-down transistor PD1 may be electrically connected to the ground terminal through a source layer contact hole in contact with the second source/drain layer located on the other side of the gate structure of the pull-down transistor PD1. Based on this, the stacked pull transistors in the first group of field-effect transistors may form an inverter. The pull-up transistor PU1 may pull up the level of the common layer, and the pull-down transistor PD1 may pull down the level of the common layer.

Correspondingly, the transistor located in the upper right corner of the second group of field-effect transistors is defined as the transmission transistor AC2; the transistor located in the lower right corner of the second group of field-effect transistors is defined as the pull-up transistor PU2; and the transistor located in the upper left corner of the second group of field-effect transistors is defined as the pull-down transistor PD2. Referring to FIG. 50, the transmission transistor AC2 is coupled with the pull-down transistor PD2 through a common layer. Moreover, based on the above content, the upper common layer and the lower common layer in the second group of field-effect transistors are coupled through a connection structure. Based on this, the electrical connection between the transmission transistor AC2, the pull-up transistor PU2, and the pull-down transistor PD2 may be achieved. In addition, the common layers used for electrical connection between the transmission transistor AC2, the pull-up transistor PU2, and the pull-down transistor PD2 correspond to the first source/drain layers of the transmission transistor AC2, the pull-up transistor PU2, and the pull-down transistor PD2. The transmission transistor AC2 may be electrically connected to the bit line terminal through a source layer contact hole in contact with the second source/drain layer located on the other side of the gate structure of the transmission transistor AC2, and the transmission transistor AC2 may be electrically connected to the word line terminal through a gate contact hole in contact with its gate structure G. The pull-up transistor PU2 may be electrically connected to the power supply terminal through a source layer contact hole in contact with the second source/drain layer located on the other side of the gate structure of the pull-up transistor PU2. The pull-down transistor PD2 may be electrically connected to the ground terminal through a source layer contact hole in contact with the second source/drain layer located on the other side of the gate structure of the pull-down transistor PD2. Based on this, the stacked pull transistors in the second group of field-effect transistors may form an inverter. The pull-up transistor PU2 may pull up the level of the common layer, and the pull-down transistor PD2 may pull down the level of the common layer.

In embodiments of the present disclosure, the gate structures of the pull-up transistor PU1 and the pull-down transistor PD1 may be electrically connected to the common drain layers in the second group of field-effect transistors through contact holes, thereby being electrically connected to the second data output terminal. The gate structures of the pull-up transistor PU2 and the pull-down transistor PD2 may be electrically connected to the common drain layers in the first group of field-effect transistors through contact holes, thereby being electrically connected to the first data output terminal. The gate structure of each of the transmission transistor AC1 and the transmission transistor AC2 may be electrically connected to the word line terminal through the contact hole, thereby achieving the SRAM structure in the present disclosure.

The above have described embodiments of the present disclosure. However, these embodiments are for illustrative purposes only and not to limit the scope of the present disclosure. Although various embodiments have been described separately above, it does not mean that the measures in various embodiments cannot be effectively combined. The scope of the present disclosure is defined by the appended claims and their equivalents. Without departing from the scope of the present disclosure, those skilled in the art may make various substitutions and modifications, all of which should fall within the scope of the present disclosure.

What is claimed is:

1. A method of manufacturing a vertically stacked semiconductor device, comprising:
sequentially providing a lower stack, an intermediate layer, and an upper stack on a substrate, each of the lower stack and the upper stack comprising channel layers and sacrificial layers provided alternately, and the sacrificial layer and the intermediate layer having etching selectivity relative to the substrate and the channel layer;
patterning the lower stack, the intermediate layer, the upper stack and an upper portion of the substrate to form a fin extending in a first direction;
forming a sacrificial gate extending in a second direction intersecting the first direction on the substrate to intersect with the fin;
forming a gate spacer on a sidewall of the sacrificial gate;
patterning the lower stack, the intermediate layer, and the upper stack using the sacrificial gate and the gate spacer as a mask, so that the patterned lower stack, the patterned intermediate layer, and the patterned upper stack comprise a side surface exposed in the first direction;
selectively etching the sacrificial layer and the intermediate layer via the exposed side surface, wherein in the selective etching, an etching rate of the intermediate layer is greater than an etching rate of the sacrificial layer, so that when the selective etching is completed, the intermediate layer is removed, the sacrificial layer is retained, and an end portion of the retained sacrificial layer in the first direction is recessed relative to the channel layer;
filling a space released by the selective etching of the sacrificial layer and the intermediate layer in the fin with a dielectric material, wherein a portion of the dielectric material filled at the end portion of the retained sacrificial layer is used as an inner spacer, and a portion of the dielectric material filled between the lower stack and the upper stack is used as an inter-device isolation layer;
forming a lower source/drain layer adjacent to an exposed side surface of the channel layer in the lower stack, and forming an upper source/drain layer adjacent to an exposed side surface of the channel layer in the upper stack; and
replacing the sacrificial gate and the sacrificial layer with a gate stack.

2. The method according to claim 1, wherein a material type of the intermediate layer is identical to a material type of the sacrificial layer, and an element doping ratio of the intermediate layer is different from an element doping ratio of the sacrificial layer, so that the etching rate of the intermediate layer is greater than the etching rate of the sacrificial layer.

3. The method according to claim 1, further comprising:
forming an intermediate dielectric layer covering the upper stack, the upper source/drain layer, and the lower source/drain layer;
etching the intermediate dielectric layer to form a dielectric layer opening exposing the upper source/drain layer and the lower source/drain layer; and
providing a conductive material in the dielectric layer opening to form a contact hole, wherein the contact hole in the intermediate dielectric layer allows an upper drain layer and a lower drain layer to be electrically connected to a data output terminal through the contact hole, and allows: a non-powered lower source layer that is not electrically connected to a power supply to be electrically connected to a ground terminal, and an upper source layer located directly above the non-powered lower source layer to be electrically connected to the ground terminal; or an upper source layer located directly above a powered lower source layer electrically connected to the power supply to be electrically connected to a bit line terminal.

4. The method according to claim 3, wherein a shallow trench isolation component is provided next to the upper portion of the substrate; and the shallow trench isolation component is pre-embedded with a power rail for electrically connecting to the power supply; and
wherein the method further comprises:
etching the shallow trench isolation component according to a position of the lower source layer and a position of the power rail, so as to form an isolation component opening that exposes the lower source layer and the power rail; and
filling the isolation component opening with a conductive material, and sealing the isolation component opening with a dielectric material after filling the conductive material, so as to form a contact hole for electrically connecting the lower source layer to the power rail.

5. The method according to claim 1, wherein the forming a lower source/drain layer adjacent to an exposed side surface of the channel layer in the lower stack and forming an upper source/drain layer adjacent to an exposed side surface of the channel layer in the upper stack comprises:
forming a protective spacer on the substrate to protect the upper stack;
forming a first electrode material layer adjacent to the lower stack in an unprotected region between the protective spacer and the substrate;
in-situ doping the first electrode material layer to obtain the lower source/drain layer;
depositing a dielectric material on the lower source/drain layer to form the inter-device isolation layer isolating the lower source/drain layer from the upper source/drain layer;
removing the protective spacer exposed outside the inter-device isolation layer;
forming a second electrode material layer adjacent to the upper stack on the inter-device isolation layer;
in-situ doping the second electrode material layer to form the upper source/drain layer; and
activating the lower source/drain layer and the upper source/drain layer.

6. A vertically stacked semiconductor device, comprising:
a first field-effect transistor and a second field-effect transistor stacked in a vertical direction on a substrate; and
an inter-device isolation layer between the first field-effect transistor and the second field-effect transistor,
wherein each of the first field-effect transistor and the second field-effect transistor comprises:
a plurality of channel layers stacked spaced apart from each other in the vertical direction;
source/drain layers adjacent to the plurality of channel layers on both sides of the plurality of channel layers in a first direction;
a gate stack extending in a second direction intersecting the first direction and surrounding the plurality of channel layers; and
an inner spacer between the gate stack and the source/drain layers,
wherein an outer surface of the inner spacer of the first field-effect transistor is substantially aligned with an outer surface of the inner spacer of the second field-effect transistor.

7. The vertically stacked semiconductor device according to claim 6,
wherein the inter-device isolation layer is integrated with the inner spacer adjacent to the inter-device isolation layer.

8. The vertically stacked semiconductor device according to claim 6,
wherein in the first field-effect transistor, the gate stack comprises a portion on an upper surface of a topmost channel layer among the plurality of channel layers in the first field-effect transistor, and
wherein in the second field-effect transistor, the gate stack comprises a portion on a lower surface of a bottommost channel layer among the plurality of channel layers in the second field-effect transistor.

9. The vertically stacked semiconductor device according to claim 6, a plurality of groups of vertically stacked field-effect transistors are provided, each group of vertically stacked field-effect transistors comprises the first field-effect transistor and the second field-effect transistor stacked vertically, two groups of vertically stacked field-effect transistors among the plurality of groups of vertically stacked field-effect transistors form an inverter structure, and a plurality of inverter structures in the vertically stacked semiconductor devices are cross coupled with each other to form an SRAM structure.

10. The vertically stacked semiconductor device according to claim 9,
wherein for the two groups of vertically stacked field-effect transistors used to form the inverter structure, drain layers of the two groups of vertically stacked field-effect transistors are shared, and the shared drain layers are electrically connected to a signal output terminal; and
wherein among the two groups of vertically stacked field-effect transistors, two source layers of one group of vertically stacked field-effect transistors are electrically connected to a ground terminal, and two source layers of the other group of vertically stacked field-effect transistors are electrically connected to a bit line terminal and a power rail, respectively.
